(19) United States
(12) Patent Application Publication
(10) Pub. No.: US 2025/0097328 A1
(43) Pub. Date: Mar. 20, 2025

(54) ELECTRONIC DEVICE

(71) Applicant: Samsung Display Co., LTD., Yongin-si (KR)

(72) Inventors: DONGHYUN SON, Yongin-si (KR); SEONGJUN LEE, Yongin-si (KR); SOLA LEE, Yongin-si (KR); KIYOUNG KIM, Yongin-si (KR)

(21) Appl. No.: 18/889,690

(22) Filed: Sep. 19, 2024

(30) Foreign Application Priority Data
Sep. 20, 2023 (KR) 10-2023-0125196

(51) Int. Cl. H04M 1/02; H01L 33/44; H01L 33/54; H01L 33/62

(52) U.S. Cl. CPC H04M 1/0214; H10H 20/84; H10H 20/853; H10H 20/857

(57) ABSTRACT

An electronic device includes a display panel including a first region and a second region spaced apart from the first region, in which the first region includes an element region, a transmissive region disposed adjacent to the element region, a copy element region spaced apart from the element region and partially surrounded by the transmissive region, and a bridge region connected to the copy element region and the element region. The display panel includes a plurality of light emitting elements disposed in the element region and a copy light emitting element that operates in synchronization with one of the plurality of light emitting elements and that is disposed in the copy element region, where the copy element region overlaps a center of a transmissive edge that defines the transmissive region.

This application claims priority to Korean Patent Application No. 10-2023-0125196, filed on Sep. 20, 2023, and all the benefits accruing therefrom under 35 U.S.C. § 119, the content of which in its entirety is herein incorporated by reference.

### BACKGROUND

### 1. Field

The present invention relates to an electronic device, and more particularly to an electronic device including a display panel with improved display quality and product performance.

### 2. Description of Related Art

An electronic device may be a device including various electronic parts such as a display panel, an electronic module, and the like. The electronic module may include a camera, an infrared sensor, a proximity sensor, or the like. The electronic module may be disposed under the display panel. One partial region of the display panel may have a higher transmittance than another partial region of the display panel. The electronic module may receive an external input through the one partial region of the display panel or may provide an output through the one partial region of the display panel.

### SUMMARY

Embodiments of the present invention provide an electronic device with improved display quality and product performance.

According to an embodiment, an electronic device includes a display panel including a first region and a second region which is spaced apart from the first region, in which the first region includes an element region, a transmissive region disposed adjacent to the element region, a copy element region spaced apart from the element region and partially surrounded by the transmissive region, and a bridge region connected to the copy element region and the element region. The display panel includes a plurality of light emitting elements disposed in the element region and a copy light emitting element that operates in synchronization with one of the plurality of light emitting elements, where the copy light emitting element is disposed in the copy element region, and where the copy element region overlaps a center of a transmissive edge that defines the transmissive region.

In an embodiment, the bridge region may include a first edge that extends from the transmissive edge to the copy element region and a second edge that extends from the transmissive edge to the copy element region, where both the first edge and the second edge may have a curvature.

In an embodiment, a radius of curvature of the first edge may be different from a radius of curvature of the second edge.

In an embodiment, a radius of curvature of the first edge and a radius of curvature of the second edge may be smaller than a radius of curvature of the transmissive edge.

In an embodiment, the copy element region may have a circular shape, and a radius of curvature of the first edge and a radius of curvature of the second edge may be greater than a radius of curvature of the copy element region.

In an embodiment, the transmissive region may include a plurality of transmissive regions, the copy element region may include a plurality of copy element regions, and the bridge region may include a plurality of bridge regions. The plurality of copy element regions may overlap centers of the plurality of transmissive regions in a one-to-one correspondence.

In an embodiment, the plurality of bridge regions may be connected to the plurality of copy element regions in a one-to-one correspondence.

In an embodiment, the plurality of bridge regions may have the same shape.

In an embodiment, shapes of the plurality of bridge regions may have rotational symmetry.

In an embodiment, the sum of shapes of the bridge regions disposed adjacent to each other among the plurality of bridge regions may constitute at least a portion of a circular ring.

In an embodiment, one or more bridge regions among the plurality of bridge regions may be connected to one copy element region among the plurality of copy element regions.

In an embodiment, the one or more bridge regions may include a first bridge region and a second bridge region, and the first bridge region and the second bridge region may extend from the one copy element region in opposite directions.

In an embodiment, the copy element region may have a polygonal shape.

In an embodiment, the display panel may further include a base layer, a circuit layer disposed on the base layer and that includes a plurality of conductive layers, an element layer that is disposed on the circuit layer and that includes the plurality of light emitting elements and the copy light emitting element, and an encapsulation layer disposed on the element layer. Each of the plurality of light emitting elements and the copy light emitting element may include a pixel electrode, an emissive layer disposed on the pixel electrode, and a common electrode disposed on the emissive layer. The common electrode may include an electrode opening defined therein to overlap the transmissive region.

In an embodiment, the display panel may further include a lower light blocking layer disposed between the base layer and the circuit layer. The lower light blocking layer may overlap the element region, the copy element region, and the bridge region and may include an opening defined therein to overlap the transmissive region.

In an embodiment, at least one bridge layer may be disposed in the bridge region and may include the same material as at least one of the plurality of conductive layers.

In an embodiment, the element layer may further include a pixel defining layer that is disposed on the circuit layer and that includes a pixel defining opening defined therein to expose at least a portion of the pixel electrode, and where a bridge layer including the same material as the pixel defining layer may be disposed in the bridge region.

In an embodiment, the display panel may further include a dividing layer that is disposed on the encapsulation layer and that includes a dividing opening and a transmissive opening defined therein. The dividing opening may overlap the pixel electrode, and the transmissive opening may overlap the transmissive region. A bridge layer including the same material as the dividing layer may be disposed in the bridge region.

In an embodiment, the plurality of light emitting elements may include a first light emitting element that emits red light, a second light emitting element that emits green light, and a third light emitting element that emits blue light, and where the copy light emitting element may operate in synchronization with the second light emitting element and may emit green light.

According to an embodiment, an electronic device includes a display panel including a first region and a second region spaced apart from the first region, in which the first region includes an element region, a transmissive region disposed adjacent to the element region, a copy element region spaced apart from the element region and partially surrounded by the transmissive region, and a bridge region connected to the copy element region and the element region. The display panel includes a plurality of light emitting elements disposed in the element region and a copy light emitting element that operates in synchronization with one of the plurality of light emitting elements and that is disposed in the copy element region. The bridge region includes a first edge that extends to the copy element region from a transmissive edge that defines the transmissive region and a second edge that extends to the copy element region from the transmissive edge, where a radius of curvature of the first edge is different from a radius of curvature of the second edge.

In an embodiment, the radius of curvature of the first edge and the radius of curvature of the second edge may be smaller than a radius of curvature of the transmissive edge.

In an embodiment, the copy element region may have a circular shape, and the radius of curvature of the first edge and the radius of curvature of the second edge may be greater than a radius of curvature of the copy element region.

In an embodiment, the transmissive region may include a plurality of transmissive regions, the copy element region may include a plurality of copy element regions, and the bridge region may include a plurality of bridge regions. The plurality of copy element regions may overlap centers of the plurality of transmissive regions in a one-to-one correspondence. The plurality of bridge regions may be connected to the plurality of copy element regions in a one-to-one correspondence. Shapes of the plurality of bridge regions may have rotational symmetry.

In an embodiment, the sum of the shapes of the bridge regions disposed adjacent to each other among the plurality of bridge regions may constitute at least a portion of a circular ring.

According to an embodiment, an electronic device includes a display panel including a first region and a second region spaced apart from the first region, in which the first region includes an element region, a transmissive region disposed adjacent to the element region, a copy element region spaced apart from the element region and partially surrounded by the transmissive region, and a bridge region connected to the copy element region and the element region. The display panel includes a first light emitting element that is disposed in the element region and that emits red light, a second light emitting element that is disposed in the element region and that emits green light, a third light emitting element that is disposed in the element region and that emits blue light, and a copy light emitting element that is disposed in the copy element region and that operates in synchronization with the second light emitting element and emits the green light. Only the copy light emitting element is disposed in the copy element region.

### BRIEF DESCRIPTION OF THE FIGURES

The above and other objects and features of the invention will become apparent by describing in detail embodiments thereof with reference to the accompanying drawings.

FIG. 1A is a perspective view of an electronic device, according to an embodiment.

FIG. 1B is a perspective view of an electronic device, according to an embodiment.

FIG. 2A is an exploded perspective view of the electronic device, according to an embodiment.

FIG. 2B is a block diagram of the electronic device, according to an embodiment.

FIG. 3 is a sectional view of a display device, according to an embodiment.

FIG. 4 is a plan view of a display panel, according to an embodiment.

FIG. 5 is an equivalent circuit diagram of a pixel, according to an embodiment.

FIG. 6A is a plan view illustrating a first region of the display panel, according to an embodiment.

FIG. 6B is a plan view illustrating a second region of the display panel, according to an embodiment.

FIG. 7A is a sectional view illustrating the first region of the display panel, according to an embodiment.

FIG. 7B is a sectional view illustrating the second region of the display panel, according to an embodiment.

FIG. 7C is a sectional view illustrating the first region of the display panel, according to an embodiment.

FIG. 8A is a plan view illustrating a portion of a first lower light blocking layer, according to an embodiment.

FIG. 8B is a plan view illustrating a portion of a second lower light blocking layer, according to an embodiment.

FIG. 9 is a plan view illustrating the first region of the display panel, according to an embodiment.

FIG. 10 is an image for explaining a relationship between radii of curvature, according to an embodiment.

FIG. 11 is a plan view illustrating the first region of the display panel, according to an embodiment.

FIG. 12 is an image for explaining a relationship between bridge regions, according to an embodiment.

FIG. 13 is an image for explaining a relationship between bridge regions, according to an embodiment.

FIG. 14 is a plan view illustrating the first region of the display panel, according to an embodiment.

FIG. 15 is a plan view illustrating the first region of the display panel, according to an embodiment.

FIG. 16 is a plan view illustrating the first region of the display panel, according to an embodiment.

FIG. 17 is a plan view illustrating the first region of the display panel, according to an embodiment.

FIG. 18 is a sectional view of the display panel, according to an embodiment.

FIG. 19 is a sectional view of the display panel, according to an embodiment.

FIG. 20 is a sectional view of the display panel, according to an embodiment.

FIG. 21 is a sectional view of the display panel, according to an embodiment.

### DETAILED DESCRIPTION

In this specification, when it is mentioned that a component (or, an area, a layer, a part, etc.) is referred to as being “on”, “connected to” or “coupled to” another component, this means that the component may be disposed directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the invention, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the invention pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

The terms “part” and “unit” mean a software component or a hardware component that performs a specific function. The hardware component may include, for example, a field-programmable gate array (FPGA) or an application-specific integrated circuit (ASIC). The software component may refer to executable code and/or data used by executable code in an addressable storage medium. Thus, software components may be, for example, object-oriented software components, class components, and working components, and may include processes, functions, properties, procedures, subroutines, program code segments, drivers, firmware, micro-codes, circuits, data, databases, data structures, tables, arrays or variables.

Hereinafter, embodiments of the invention will be described with reference to the accompanying drawings.

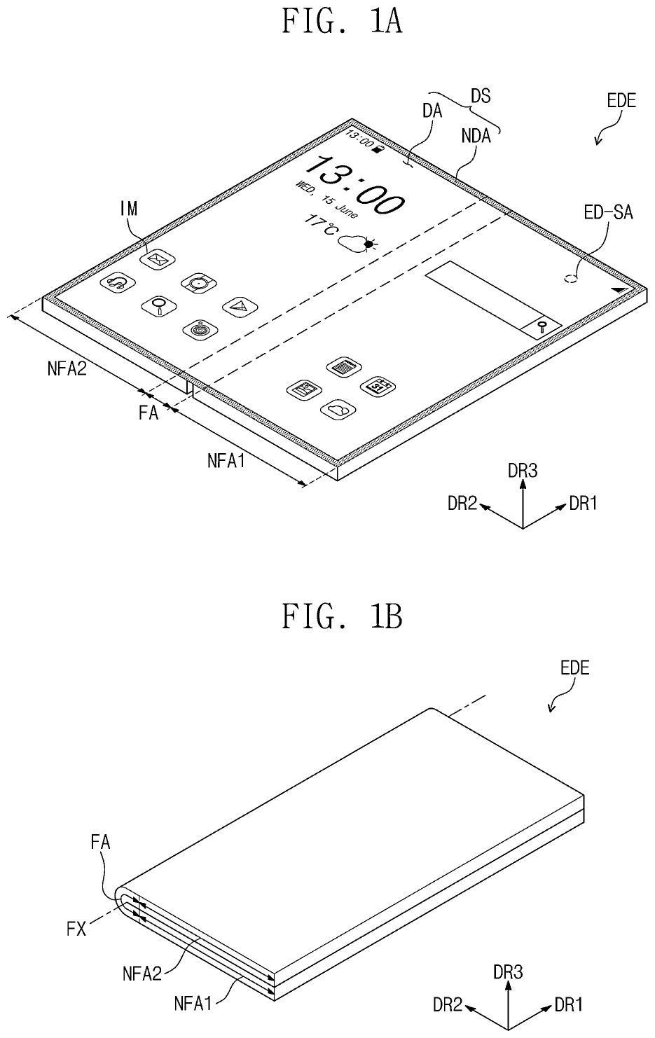

FIGS. 1A and 1B are perspective views of an electronic device EDE, according to an embodiment. FIG. 1A illustrates a flat state (or, an unfolded state) of the electronic device EDE, and FIG. 1B illustrates a folded state of the electronic device EDE.

In an embodiment and referring to FIGS. 1A and 1B, the electronic device EDE may include a display surface DS defined by a first direction DR1 and a second direction DR2 crossing the first direction DR1. The electronic device EDE may provide an image IM to a user through the display surface DS.

In an embodiment, the display surface DS may include a display region DA and a non-display region NDA disposed around the display region DA. The display region DA may display the image IM, and the non-display region NDA may not display the image IM. The non-display region NDA may surround the display region DA. However, without being limited thereto, the shape of the display region DA and the shape of the non-display region NDA may be modified.

Hereinafter, a direction substantially perpendicular to a plane defined by the first direction DR1 and the second direction DR2 is defined as a third direction DR3. In addition, the expression “when viewed from above the plane” used herein may mean that it is viewed in the third direction DR3.

In an embodiment, a sensor region ED-SA may be defined in the display region DA of the electronic device EDE. Although one sensor region ED-SA is illustrated in FIG. 1A, the number of sensor regions ED-SA is not limited thereto. The sensor region ED-SA may be a portion of the display region DA. Accordingly, the electronic device EDE may display an image through the sensor region ED-SA.

In an embodiment, an electronic module may be disposed in a region overlapping the sensor region ED-SA. The electronic module may receive an external input transferred through the sensor region ED-SA, or may provide an output through the sensor region ED-SA. For example, the electronic module may be a camera module, a sensor (e.g., a proximity sensor) that measures a distance, a sensor that recognizes a part of the user's body (e.g., a fingerprint, an iris, or a face), or a small lamp that outputs light, but is not particularly limited thereto. Hereinafter, it will be exemplified that the electronic module overlapping the sensor region ED-SA is a camera module.

In an embodiment, the electronic device EDE may include a folding region FA and a plurality of non-folding regions NFA1 and NFA2. The non-folding regions NFA1 and NFA2 may include the first non-folding region NFA1 and the second non-folding region NFA2. The folding region FA may be disposed between the first non-folding region NFA1 and the second non-folding region NFA 2. The folding region FA may be referred to as a foldable region, and the first and second non-folding regions NFA1 and NFA 2 may be referred to as first and second non-foldable regions.

In an embodiment and as illustrated in FIG. 1B, the folding region FA may be folded about a folding axis FX which is directed parallel to the first direction DR1. The folding region FA has a certain curvature and a certain radius of curvature in the folded state of the electronic device EDE. The electronic device EDE may be folded in an in-folding manner such that the first non-folding region NFA1 and the second non-folding region NFA 2 face each other and the display surface DS is not exposed to the outside.

In an embodiment, the electronic device EDE may be folded in an out-folding manner such that the display surface DS is exposed to the outside. In an embodiment, the electronic device EDE may be folded in an in-folding or out-folding manner in the flat state. However, the invention is not limited thereto. In an embodiment, the electronic device EDE may be configured to select one of an unfolding operation, an in-folding operation, and an out-folding operation. In an embodiment, a plurality of folding axes may be defined in the electronic device EDE, and the electronic device EDE may be folded about the folding axis FX in an in-folding or out-folding manner in the flat state.

In an embodiment, although the foldable electronic device EDE has been described with reference to FIGS. 1A and 1B, applications of the invention are not limited to the foldable electronic device EDE. For example, in an embodiment, the following descriptions may be applied to various electronic devices, such as a bar-type electronic device, a rollable electronic device, a slidable electronic device, and a stretchable electronic device, which do not include the folding region FA.

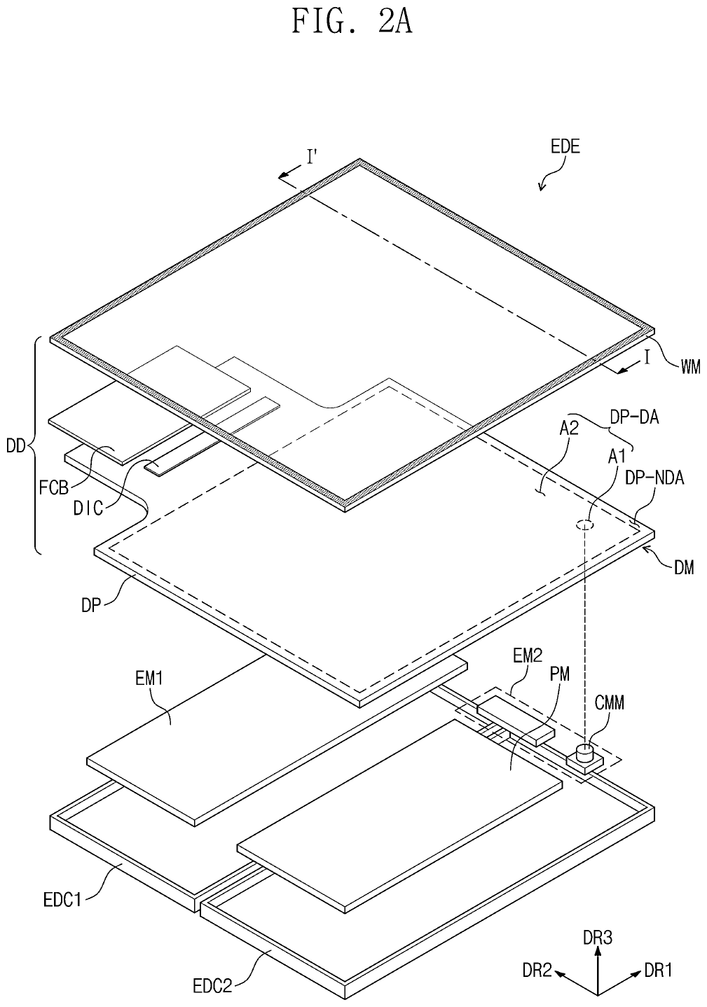

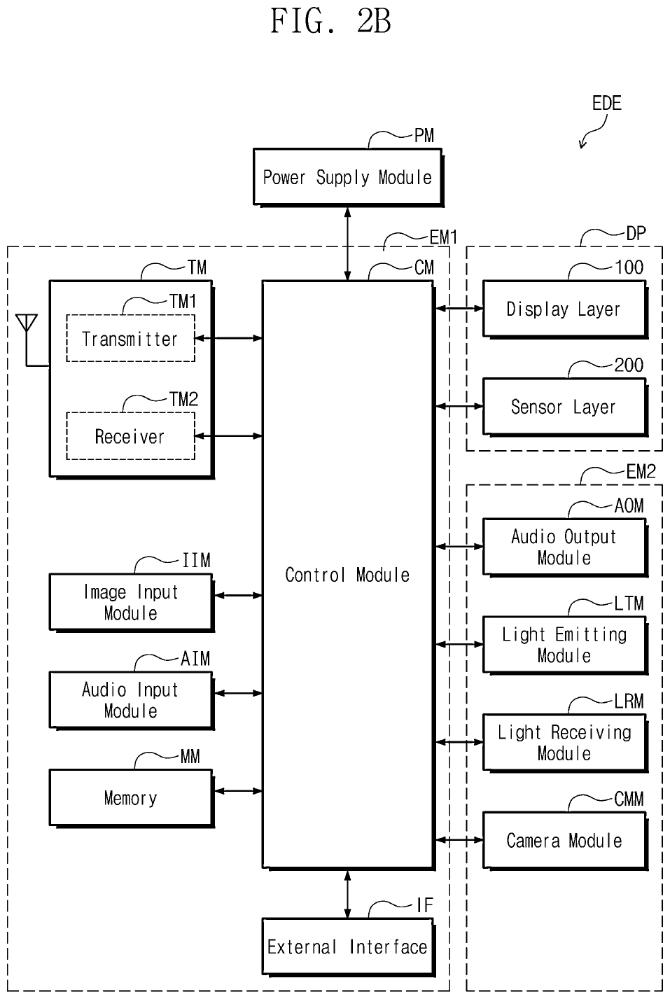

FIG. 2A is an exploded perspective view of the electronic device EDE, according to an embodiment. FIG. 2B is a block diagram of the electronic device EDE, according to an embodiment.

In an embodiment and referring to FIGS. 2A and 2B, the electronic device EDE may include a display device DD, a first electronic module EM1, a second electronic module EM2, a power supply module PM, and housings EDC1 and EDC2. The electronic device EDE may further include a mechanical structure for controlling a folding operation of the display device DD.

In an embodiment, the display device DD includes a window module WM and a display module DM. The window module WM provides the front surface of the electronic device EDE. The display module DM may include at least a display panel DP. The display module DM generates an image and senses an external input.

In an embodiment and referring to FIG. 2A, the display module DM is illustrated as being the same as the display panel DP. However, the display module DM may substantially be a stacked structure in which a plurality of components including the display panel DP are stacked one above another. The stacked structure of the display module DM will be described below in detail.

In an embodiment, the display panel DP includes a display region DP-DA and a non-display region DP-NDA that correspond to the display region DA (refer to FIG. 1A) and the non-display region NDA (refer to FIG. 1A) of the electronic device EDE. The expression “one region/portion corresponds to another region/portion” used herein means that the regions/portions overlap each other and is not limited to having the same area.

In an embodiment, the display region DP-DA may include a first region A1 and a second region A2. The second region A2 may be spaced apart from or disposed adjacent to the first region A1.

In an embodiment, the first region A1 may overlap or correspond to the sensor region ED-SA (refer to FIG. 1A) of the electronic device EDE. Although the first region A1 is illustrated as a circular shape in this embodiment, in other embodiments the first region A1 may have various shapes, such as a polygonal shape, an oval shape, a shape having at least one curved side, or an irregular shape, and is not limited to any one embodiment.

In an embodiment, the first region A1 may be referred to as a component region, and the second region A2 may be referred to as a main display region or a normal display region. The first region A1 may have a higher transmittance than the second region A2. In another embodiment, the first region A1 may have a lower resolution than the second region A2. However, the invention is not limited thereto. For example, the first region A1 may have a higher transmittance than the second region A2, but may have substantially the same resolution as the second region A2. The first region A1 may overlap a camera module CMM that will be described below.

In an embodiment, the display panel DP may include a display layer 100 and a sensor layer 200.

In an embodiment, the display layer 100 may be a component that substantially generates an image. The display layer 100 may be an emissive display layer. For example, the display layer 100 may be an organic light emitting display layer, an inorganic light emitting display layer, an organic-inorganic light emitting display layer, a quantum-dot display layer, a micro-LED display layer, or a nano-LED display layer.

In an embodiment, the sensor layer 200 may sense an external input applied from the outside. The external input may be a user input. The user input may include various types of external inputs such as a part of the user's body, light, heat, a pen, or pressure.

In an embodiment, the display module DM may include a driver IC DIC disposed on the non-display region DP-NDA. The display module DM may further include a flexible circuit film FCB coupled to the non-display region DP-NDA.

In an embodiment, the driver IC DIC may include drive elements (e.g., a data drive circuit) for driving pixels of the display panel DP. Although FIG. 2A illustrates a structure in which the driver IC DIC is mounted on the display panel DP, the invention is not limited thereto. For example, in another embodiment, the driver IC DIC may be mounted on the flexible circuit film FCB.

In an embodiment, the power supply module PM supplies power required for overall operation of the electronic device EDE. The power supply module PM may include a conventional battery module.

In an embodiment, the first electronic module EM1 and the second electronic module EM2 include various functional modules for operating the electronic device EDE. Each of the first electronic module EM1 and the second electronic module EM2 may be directly mounted on a mother board electrically connected with the display panel DP, or may be mounted on a separate substrate and electrically connected to the mother board through a connector.

In an embodiment, the first electronic module EM1 may include a control module CM, a wireless communication module TM, an image input module IIM, an audio input module AIM, a memory MM, and an external interface IF.

In an embodiment, the control module CM controls overall operation of the electronic device EDE. The control module CM may be a microprocessor. For example, the control module CM activates or deactivates the display panel DP. The control module CM may control other modules, such as the image input module IIM or the audio input module AIM, based on a touch signal received from the display panel DP.

In an embodiment, the wireless communication module TM may communicate with an external electronic device through a first network (e.g., a short-range communication network such as Bluetooth, WiFi direct, or infrared data association (IrDA)) or a second network (e.g., a long-range communication network such as a cellular network, Internet, or a computer network (e.g., LAN or WAN)). Communication modules included in the wireless communication module TM may be integrated into one component (e.g., a single chip), or may be implemented with a plurality of components (e.g., a plurality of chips) separated from one another. The wireless communication module TM may transmit/receive audio signals using a general communication line. The wireless communication module TM may include a transmitter TM1 that modulates a signal to be transmitted and transmits the modulated signal and a receiver TM2 that demodulates a received signal.

In an embodiment, the image input module IIM processes an image signal to covert the image signal into image data that is able to be displayed on the display panel DP. The audio input module AIM receives an external audio signal through a microphone in a voice recording mode or a voice recognition mode and converts the external audio signal into electrical voice data.

In an embodiment, the external interface IF may include a connector capable of physically connecting the electronic device EDE and an external electronic device. For example, the external interface IF serves as an interface between the control module CM and an external device such as an external charger, a wired/wireless data port, or a card (e.g., a memory card or a SIM/UIM card).

In an embodiment, the second electronic module EM2 may include an audio output module AOM, a light emitting module LTM, a light receiving module LRM, and the camera module CMM. The audio output module AOM converts audio data received from the wireless communication module TM or audio data stored in the memory MM and outputs the converted data to the outside.

In an embodiment, the light emitting module LTM generates and outputs light. The light emitting module LTM may output infrared light. The light emitting module LTM may include an LED element. The light receiving module LRM may sense infrared light. The light receiving module LRM may be activated when infrared light above a certain level is sensed. The light receiving module LRM may include a CMOS sensor. After infrared light generated by the light emitting module LTM is output, the infrared light may be reflected by an external object (e.g., the user's finger or face), and the reflected infrared light may be incident to the light receiving module LRM.

In an embodiment, the camera module CMM may take a still image and a video. The camera module CMM may include a plurality of camera modules. A part of the camera modules CMM may overlap the first region A1. An external input (e.g., light) may be provided to the camera module CMM through the first region A1. For example, the camera module CMM may take an external image by receiving natural light through the first region A1.

In an embodiment, the housings EDC1 and EDC2 accommodate the display module DM, the first and second electronic modules EM1 and EM2, and the power supply module PM. The housings EDC1 and EDC2 protect components, such as the display module DM, the first and second electronic modules EM1 and EM2, and the power supply module PM, which are accommodated in the housings EDC1 and EDC2. Although the two housings EDC1 and EDC2 are separated from each other as illustrated in FIG. 2A, the invention is not limited thereto. Although not illustrated, the electronic device EDE may further include a hinge structure for connecting the two housings EDC1 and EDC2. The housings EDC1 and EDC2 may be coupled with the window module WM.

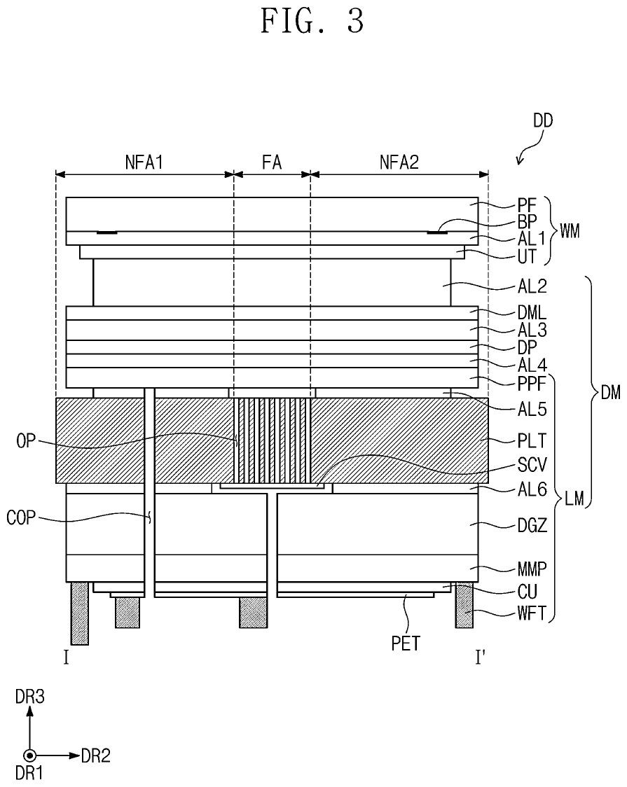

FIG. 3 is a sectional view of the display device DD, according to an embodiment. FIG. 3 is a sectional view of the display device DD taken along line I-I′ of FIG. 2A, according to an embodiment.

In an embodiment and referring to FIG. 3, the display device DD may include the window module WM and the display module DM.

In an embodiment, the window module WM may include a window UT, a protective film PF disposed on the window UT, and a bezel pattern BP.

In an embodiment, the window UT may be chemically strengthened glass. Since the window UT is applied to the display device DD, a crease may be minimized even though folding and unfolding are repeated.

In an embodiment, the protective film PF may include polyimide, polycarbonate, polyamide, triacetylcellulose, polymethylmethacrylate, or polyethylene terephthalate. Although not separately illustrated, at least one of a hard coating layer, an anti-fingerprint layer, and an anti-reflection layer may be disposed on the upper surface of the protective film PF.

In an embodiment, the bezel pattern BP overlaps the non-display region NDA (refer to FIG. 1A). The bezel pattern BP may be disposed on one surface of the window UT or one surface of the protective film PF. In FIG. 3, the bezel pattern BP disposed on the lower surface of the protective film PF is illustrated as an example. However, without being limited thereto, in another embodiment, the bezel pattern BP may be disposed on the upper surface of the protective film PF, the upper surface of the window UT, or the lower surface of the window UT. The bezel pattern BP may be a colored light-blocking film and may be formed by, for example, a coating method. The bezel pattern BP may include a base material and a dye or pigment mixed in the base material. The bezel pattern BP may have a closed-line shape when viewed from above the plane.

In an embodiment, a first adhesive layer AL1 may be disposed between the protective film PF and the window UT. The first adhesive layer AL1 may be a pressure sensitive adhesive (PSA) film or an optically clear adhesive (OCA) member. Adhesive layers to be described below may also be the same as the first adhesive layer and may include a conventional adhesive.

In an embodiment, the first adhesive layer AL1 may have a thickness sufficient to cover the bezel pattern BP. The first adhesive layer AL1 may have a thickness by which bubbles are not generated around the bezel pattern BP.

In an embodiment, the first adhesive layer AL1 may be separated from the window UT. Since the protective film PF has a lower strength than the window UT, the protective film PF may be relatively easily scratched. After the first adhesive layer AL1 and the damaged protective film PF are separated from the window UT, a new protective film PF may be attached to the window UT.

In an embodiment, the display module DM may include an impact absorbing layer DML, the display panel DP, and a lower member LM.

In an embodiment, the impact absorbing layer DML may be disposed on the display panel DP. The impact absorbing layer DML may be a functional layer for protecting the display panel DP from external impact. The impact absorbing layer DML may be coupled to the window UT through a second adhesive layer AL2 and may be coupled to the display panel DP through a third adhesive layer AL3.

In an embodiment, the lower member LM may be disposed under the display panel DP. The lower member LM may include a panel protection layer PPF, a support layer PLT, a cover layer SCV, a digitizer DGZ, a shielding layer MMP, a heat radiating layer CU, a protective layer PET, and a waterproof tape WFT. In an embodiment, the lower member LM may not include some of the aforementioned components, or may further include other components. Furthermore, the stacking sequence illustrated in FIG. 3 is illustrative, and the sequence in which the components are stacked may be changed.

In an embodiment, the panel protection layer PPF may be disposed under the display panel DP. The panel protection layer PPF may be attached to the rear surface of the display panel DP through a fourth adhesive layer AL4. The panel protection layer PPF may protect the bottom of the display panel DP. The panel protection layer PPF may include a flexible plastic material. The panel protection layer PPF may prevent a scratch on the rear surface of the display panel DP during a manufacturing process of the display panel DP. The panel protection layer PPF may be a colored polyimide film. For example, the panel protection layer PPF may be an opaque yellow film, but is not limited thereto.

In an embodiment, the support layer PLT is disposed under the panel protection layer PPF. The support layer PLT supports the components disposed on the upper side of the support layer PLT and maintains a flat state and a folded state of the display device DD. In an embodiment, the support layer PLT may include at least a first support part corresponding to the first non-folding region NFA1, a second support part corresponding to the second non-folding region NFA2, and a folding part corresponding to the folding region FA. The first support part and the second support part may be spaced apart from each other in the second direction DR2. The folding part may be disposed between the first support part and the second support part, and a plurality of openings OP may be defined in the folding part. The flexibility of a portion of the support layer PLT may be improved by the openings OP. The flexibility of the portion of the support layer PLT that overlaps the folding region FA may be improved by the openings OP.

In an embodiment, the support layer PLT may include carbon fiber reinforced plastic (CFRP), but is not particularly limited thereto. In another embodiment, the first support part and the second support part may include a non-metallic material, plastic, glass fiber reinforced plastic, or glass. The plastic may include polyimide, polyethylene, or polyethylene terephthalate and is not particularly limited. The first support part and the second support part may include the same material. The folding part may include a material that is the same as or different from that of the first support part and the second support part. For example, the folding part may include a material having an elastic modulus of about 60 GPa or more and may include a metallic material such as stainless steel. For example, the folding part may include SUS 304. However, without being limited thereto, the folding part may include various metallic materials.

In an embodiment, the support layer PLT may be attached to the panel protection layer PPF through a fifth adhesive layer AL5. A plurality of fifth adhesive layers AL5 may be provided. The fifth adhesive layers AL5 may be spaced apart from each other with the folding region FA therebetween. The fifth adhesive layer AL5 may not overlap the plurality of openings OP. Furthermore, the fifth adhesive layer AL5 may be spaced apart from the plurality of openings OP when viewed from above the plane. Since the fifth adhesive layer AL5 is not disposed in a region corresponding to the folding region FA, the flexibility of the support layer PLT may be improved.

In an embodiment, in the region overlapping the folding region FA, the panel protection layer PPF may be spaced apart from the support layer PLT. That is, in a portion overlapping the folding region FA, an empty space may be defined between the support layer PLT and the panel protection layer PPF. Since the empty space is defined between the panel protection layer PPF and the support layer PLT, the shapes of the plurality of openings OP defined in the support layer PLT may not be visible from outside the electronic device EDE (refer to FIG. 1A).

In an embodiment, the fifth adhesive layer AL5 may have a smaller thickness than the fourth adhesive layer AL4. As the thickness of the fifth adhesive layer AL5 is decreased, a step caused by the fifth adhesive layer AL5 may be decreased. As the step is decreased, deformation of stacked structures due to folding and unfolding of the electronic device EDE (refer to FIG. 1A) may be reduced. However, the plurality of openings OP may be visible, or the fifth insulating layer AL5 may be separated by repeated folding operations. As the thickness of the fifth adhesive layer AL5 is increased, the plurality of openings OP may not be visible, and the reliability of the adhesive force of the fifth adhesive layer AL5 may be raised despite repeated folding operations. However, the step may be increased. Accordingly, the thickness of the fifth adhesive layer AL5 may be selected within an appropriate range in consideration of folding reliability, adhesion reliability, and visibility of the plurality of openings OP.

In an embodiment, the cover layer SCV may be disposed under the support layer PLT. The cover layer SCV may be coupled to the support layer PLT by an adhesive member. The cover layer SCV may cover the plurality of openings OP defined in the support layer PLT. Accordingly, the cover layer SCV may prevent infiltration of foreign matter into the plurality of openings OP. The cover layer SCV may have a lower elastic modulus than the support layer PLT. For example, the cover layer SCV may include thermoplastic poly-urethane, rubber, or silicone, but is not limited thereto.

In an embodiment, the digitizer DGZ may be disposed under the support layer PLT. A plurality of digitizers DGZ may be provided. For example, the plurality of digitizers DGZ may be spaced apart from each other in the second direction DR2. One portion of each of the plurality of digitizers DGZ may overlap the non-folding region NFA1 or NFA2, and the remaining portion may overlap the folding region FA. A portion of each of the plurality of digitizers DGZ may overlap some of the plurality of openings OP when viewed from above the plane.

In an embodiment, each of the plurality of digitizers DGZ may include a plurality of loop coils that generate a magnetic field at a preset resonant frequency with an input device (hereinafter, referred to as the pen). The plurality of digitizers DGZ may be referred to as an EMR detection panel. In an embodiment, the plurality of digitizers DGZ may be omitted.

In an embodiment, the magnetic field formed in the plurality of digitizers DGZ is applied to an LC resonance circuit of the pen that is constituted by an inductor (a coil) and a capacitor. The coil generates a current by the received magnetic field and transfers the generated current to the capacitor. Accordingly, the capacitor charges the current input from the coil and discharges the charged current to the coil. Thus, the magnetic field at the resonant frequency is emitted to the coil. The magnetic field emitted by the pen may be absorbed by the loop coils of the plurality of digitizers DGZ again, and thus the position of the pen adjacent to the plurality of digitizers DGZ may be determined.

In an embodiment, a plurality of shielding layers MMP may be provided. The shielding layers MMP may be disposed under the plurality of digitizers DGZ, respectively. The shielding layers MMP may include magnetic metal powder. The shielding layers MMP may be referred to as a magnetic metal powder layer, a magnetic layer, a magnetic circuit layer, or a magnetic path layer. The shielding layers MMP may shield a magnetic field.

In an embodiment, a plurality of heat radiating layers CU may be provided. The heat radiating layers CU may be disposed under the shielding layers MMP, respectively. The heat radiating layers CU may be sheets having high thermal conductivity. For example, the heat radiating layers CU may include graphite, copper, or a copper alloy, but are not particularly limited thereto.

In an embodiment, a plurality of protective layers PET may be provided. The protective layers PET may be disposed under the heat radiating layers CU, respectively. The protective layers PET may be insulating layers. For example, the protective layers PET may be layers provided to prevent introduction of static electricity. Accordingly, the protective layers PET may prevent the flexible circuit film FCB (refer to FIG. 2A) from electrically interfering with members disposed on the protective layers PET.

In an embodiment, a plurality of waterproof tapes WFT may be provided. The waterproof tapes WFT may be attached to the shielding layers MMP and the protective layers PET. The waterproof tapes WFT may be attached to a set bracket (not illustrated). The thickness of waterproof tapes attached to the shielding layers MMP and the thickness of waterproof tapes attached to the protective layers PET among the waterproof tapes WFT may differ from each other.

In an embodiment, a through-hole COP may be defined in at least some components constituting the lower member LM. The through-hole COP may overlap or correspond to the sensor region ED-SA (refer to FIG. 1A) of the electronic device EDE. At least a portion of the camera module CMM (refer to FIG. 2A) may be inserted into the through-hole COP.

In an embodiment and referring to FIG. 3, the through-hole COP is illustrated as being provided from the rear surface of one protective layer among the protective layers PET to the fifth adhesive layer AL5. However, the invention is not limited thereto. For example, in another embodiment, the through-hole COP may be provided from the rear surface of the one protective layer to the upper surface of the panel protection layer PPF or from the rear surface of the one protective layer to the upper surface of the fourth adhesive layer AL4.

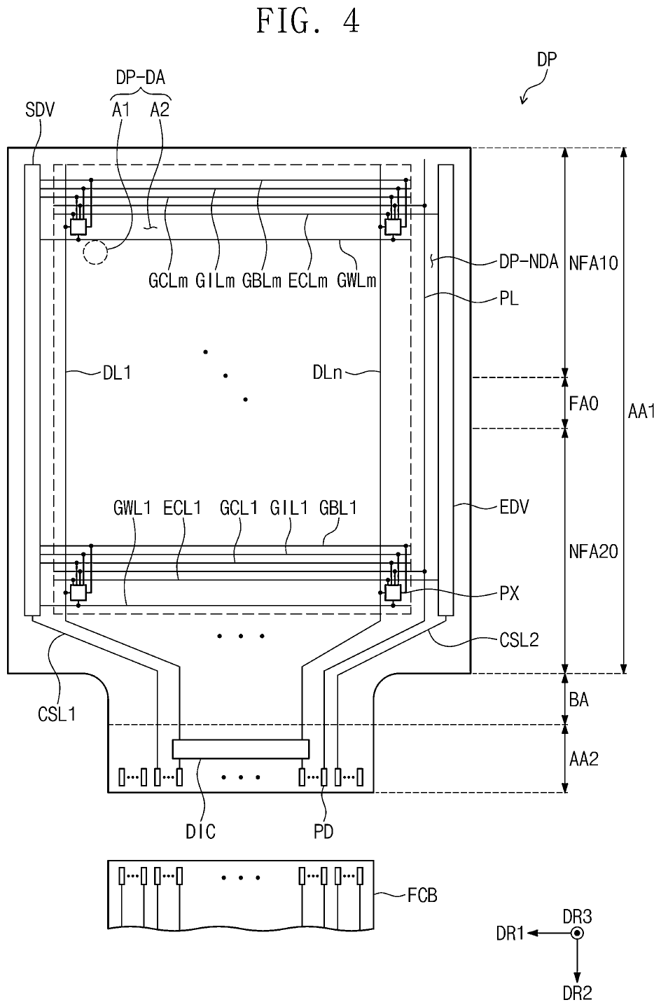

FIG. 4 is a plan view of the display panel DP, according to an embodiment.

In an embodiment and referring to FIG. 4, the display region DP-DA and the non-display region DP-NDA disposed around the display region DP-DA may be defined in the display panel DP. The display region DP-DA and the non-display region DP-NDA may be distinguished from each other depending on whether pixels PX are disposed. The pixels PX are disposed in the display region DP-DA. A scan driver SDV, a data driver, and an emission driver EDV may be disposed in the non-display region DP-NDA. The data driver may be a circuit configured in the driver IC DIC.

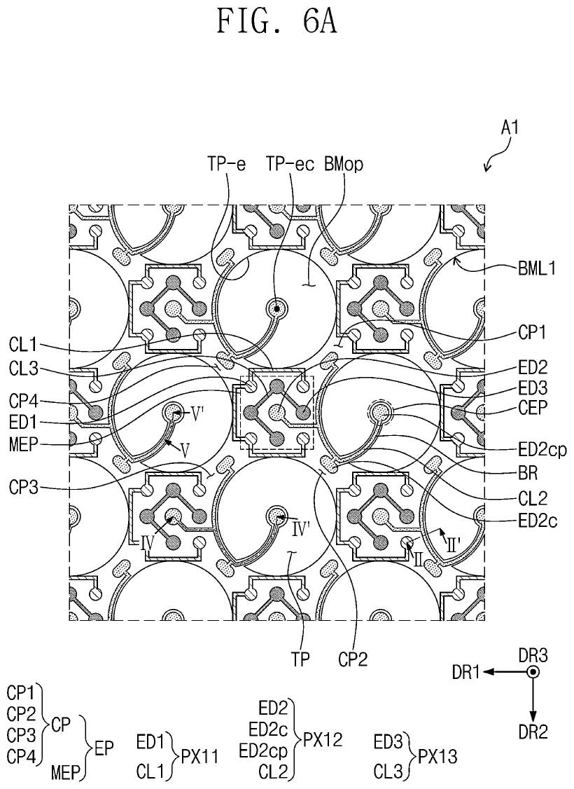

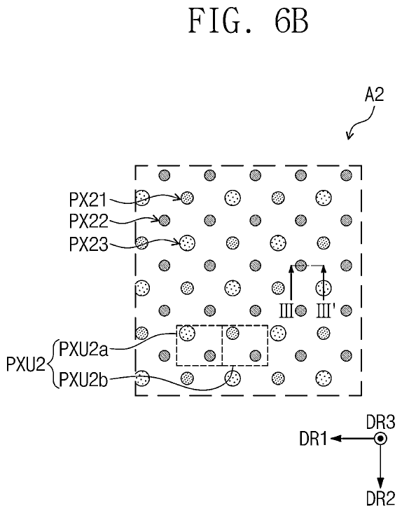

In an embodiment, the display region DP-DA may include the first region A1 and the second region A2. The first region A1 and the second region A2 may be distinguished from each other depending on the arrangement spacing between the pixels PX, the size of the pixels PX, the shape of the pixels PX, or the presence or absence of a transmissive region TP (refer to FIG. 6A).

In an embodiment, the display panel DP may include a first panel region AA1, a bending region BA, and a second panel region AA2 that are defined in the second direction DR2. The second panel region AA2 and the bending region BA may be partial regions of the non-display region DP-NDA. The bending region BA is disposed between the first panel region AA1 and the second panel region AA2.

In an embodiment, the first panel region AA1 may be a region corresponding to the display surface DS of FIG. 1A. The first panel region AA1 may include a first non-folding region NFA10, a second non-folding region NFA20, and a folding region FAO. The first non-folding region NFA10, the second non-folding region NFA20, and the folding region FAO correspond to the first non-folding region NFA1, the second non-folding region NFA2, and the folding region FA of FIGS. 1A and 1B, respectively.

In an embodiment, the width of the bending region BA and the width (or, length) of the second panel region AA2 that are directed parallel to the first direction DR1 may be smaller than the width (or, length) of the first panel region AA1 that is directed parallel to the first direction DR1. The regions having a smaller length in the direction of a bending axis may be more easily bent.

In an embodiment, the display panel DP may include the pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a drive voltage line PL, and a plurality of pads PD. Here, “m” and “n” are natural numbers of 2 or larger.

In an embodiment, the pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

In an embodiment, the initialization scan lines GIL1 to GILm, the compensation scan lines GCL1 to GCLm, the write scan lines GWL1 to GWLm, and the black scan lines GBL1 to GBLm may extend in the first direction DR1 and may be electrically connected to the scan driver SDV. The data lines DL1 to DLn may extend in the second direction DR2 and may be electrically connected to the driver IC DIC via the bending region BA. The emission control lines ECL1 to ECLm may extend in a direction parallel to the first direction DR1 and may be electrically connected to the emission driver EDV.

In an embodiment, the drive voltage line PL may include a portion extending in the first direction DR1 and a portion extending in the second portion DR2. The portion extending in the first direction DR1 and the portion extending in the second portion DR2 may be disposed on different layers. The portion of the drive voltage line PL that extends in the second direction DR2 may extend to the second panel region AA2 via the bending region BA. The drive voltage line PL may provide a drive voltage to the pixels PL.

In an embodiment, the first control line CSL1 may be connected to the scan driver SDV and may extend toward a lower end of the second panel region AA2 via the bending region BA. The second control line CSL2 may be connected to the emission driver EDV and may extend toward the lower end of the second panel region AA2 via the bending region BA.

In an embodiment, the pads PD may be disposed adjacent to the lower end of the second panel region AA2 when viewed from above the plane. The driver IC DIC, the drive voltage line PL, the first control line CSL1, and the second control line CSL2 may be electrically connected to the pads PD. The flexible circuit film FCB may be electrically connected to the pads PD through an anisotropic conductive adhesive layer.

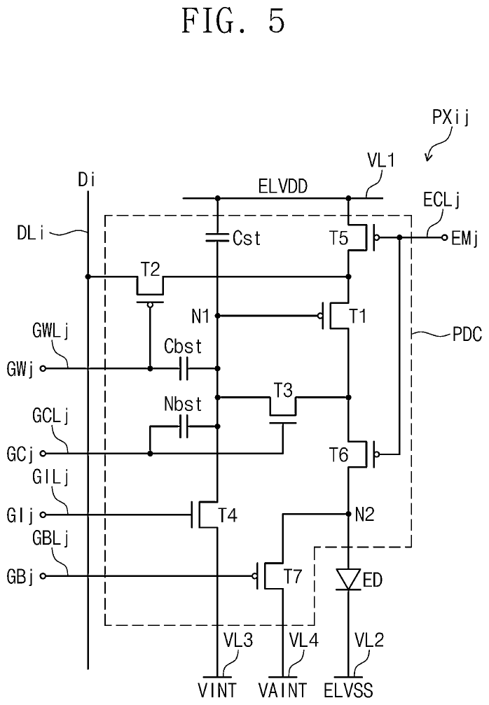

FIG. 5 is an equivalent circuit diagram of a pixel PXij, according to an embodiment.

In an embodiment and referring to FIG. 5, an equivalent circuit diagram of one pixel PXij among the plurality of pixels PX (refer to FIG. 4) is illustrated as an example. Since the plurality of pixels PX have the same circuit structure, description of the circuit structure for the pixel PXij may be applied to the remaining pixels PX, and detailed description of the remaining pixels PX will be omitted.

In an embodiment and referring to FIGS. 4 and 5, the pixel PXij is connected to the i-th data line DLi among the data lines DL1 to DLn, the j-th initialization scan line GILj among the initialization scan lines GIL1 to GILm, the j-th compensation scan line GCLj among the compensation scan lines GIL1 to GILm, the j-th write scan line GWLj among the write scan lines GWL1 to GWLm, the j-th black scan line GBLj among the black scan lines GBL1 to GBLm, the j-th emission control line ECLj among the emission control lines ECL1 to ECLm, first and second drive voltage lines VL1 and VL2, respectively, and first and second initialization voltage lines VL3 and VL4, respectively. Here, “i” is an integer of 1 to n, and “j” is an integer of 1 to m.

In an embodiment, the pixel PXij includes a light emitting element ED and a pixel circuit PDC. The light emitting element ED may be a light emitting diode. In an embodiment, the light emitting element ED may be an organic light emitting diode including an organic light emitting layer, but is not particularly limited thereto. The pixel circuit PDC may control the amount of current flowing through the light emitting element ED in response to a data signal Di. The light emitting element ED may emit light having a certain luminance in response to the amount of current provided from the pixel circuit PDC. In this specification, the amount of current of the pixel PXij may mean the amount of current provided to the light emitting element ED.

In an embodiment, the pixel circuit PDC may include first to seventh transistors T1, T2, T3, T4, T5, T6, and T7, respectively, and first to third capacitors Cst, Cbst, and Nbst, respectively. The configuration of the pixel circuit PDC according to an embodiment is not limited to the embodiment illustrated in FIG. 5. The pixel circuit PDC illustrated in FIG. 5 is merely illustrative, and various changes and modifications may be made to the configuration of the pixel circuit PDC.

In an embodiment, at least one of the transistors T1, T2, T3, T4, T5, T6, and T7 may be a transistor having a low-temperature polycrystalline silicon (LTPS) semiconductor layer. At least one of the transistors T1, T2, T3, T4, T5, T6, and T7 may be a transistor having an oxide semiconductor layer. For example, the third and fourth transistors T3 and T4, respectfully, may be oxide semiconductor transistors, and the first, second, fifth, sixth, and seventh transistors T1, T2, T5, T6, and T7, respectively, may be LTPS transistors.

In an embodiment, the first transistor T1 (or, referred to as a drive transistor) directly affecting the brightness of the light emitting element ED may include a semiconductor layer formed of polycrystalline silicon having high reliability, and thus the display device DD having a high resolution may be implemented. Meanwhile, an oxide semiconductor has high carrier mobility and low leakage current, and thus a voltage drop is not great even though operating time is long. That is, the color of an image is not greatly changed depending on a voltage drop even during a low-frequency operation, and thus the low-frequency operation is possible. Since the oxide semiconductor has an advantage of low leakage current as described above, at least one of the third transistor T3, which is connected with a gate electrode of the first transistor T1, and the fourth transistor T4 may be employed as an oxide semiconductor to reduce power consumption while preventing leakage current that is likely to flow to the gate electrode.

In an embodiment, some of the transistors T1, T2, T3, T4, T5, T6, and T7 may be P-type transistors, and the others may be N-type transistors. For example, the first, second, fifth, sixth, and seventh transistors T1, T2, T5, T6, and T7, respectively, may be P-type transistors, and the third and fourth transistors T3 and T4, respectively, may be N-type transistors.

In an embodiment, the configuration of the pixel circuit PDC according to an embodiment is not limited to the embodiment illustrated in FIG. 5. The pixel circuit PDC illustrated in FIG. 5 is merely illustrative, and various changes and modifications may be made to the configuration of the pixel circuit PDC. For example, the transistors T1, T2, T3, T4, T5, T6, and T7 may all be P-type transistors or N-type transistors. In another embodiment, the first, second, fifth, and sixth transistors T1, T2, T5, and T6, respectively, may be P-type transistors, and the third, fourth, and seventh transistors T3, T4, and T7, respectively, may be N-type transistors.

In an embodiment, the j-th initialization scan line GILj, the j-th compensation scan line GCLj, the j-th write scan line GWLj, the j-th black scan line GBLj, and the j-th emission control line ECLj may transfer the j-th initialization scan signal GIj, the j-th compensation scan signal GCj, the j-th write scan signal GWj, the j-th black scan signal GBj, and the j-th emission control signal EMj to the pixel PXij, respectively. The i-th data line DLi transfers the i-th data signal Di to the pixel PXij. The i-th data signal Di may have a voltage level corresponding to an image signal that is input to the display device DD (refer to FIG. 3).

In an embodiment, the first drive voltage line VL1 and the second drive voltage line VL2 may transfer a first drive voltage ELVDD and a second drive voltage ELVSS to the pixel PXij, respectively. In addition, the first initialization voltage line VL3 and the second initialization voltage line VL4 may transfer a first initialization voltage VINT and a second initialization voltage VAINT to the pixel PXij, respectively.

In an embodiment, the first transistor T1 is connected between the first drive voltage line VL1, which receives the first drive voltage ELVDD, and the light emitting element ED. The first transistor T1 includes a first electrode connected with the first drive voltage line VL1 via the fifth transistor T5, a second electrode connected with a pixel electrode (or, referred to as an anode) of the light emitting element ED via the sixth transistor T6, and a third electrode (e.g., a gate electrode) connected with one end of the first capacitor Cst (e.g., a first node N1). The first transistor T1 may receive the i-th data signal Di that the i-th data line DLi transfers depending on a switching operation of the second transistor T2 and may supply a drive current to the light emitting element ED.

In an embodiment, the second transistor T2 is connected between the i-th data line DLi and the first electrode of the first transistor T1. The second transistor T2 includes a first electrode connected with the i-th data line DLi, a second electrode connected with the first electrode of the first transistor T1, and a third electrode (e.g., a gate electrode) connected with the j-th write scan line GWLj. The second transistor T2 may be turned on depending on the j-th write scan signal GWj transferred through the j-th write scan line GWLj and may transfer, to the first electrode of the first transistor T1, the i-th data signal Di transferred from the i-th data line DLi. One end of the second capacitor Cbst may be connected to the third electrode of the second transistor T2, and an opposite end of the second capacitor Cbst may be connected to the first node N1.

In an embodiment, the third transistor T3 is connected between the second electrode of the first transistor T1 and the first node N1. The third transistor T3 includes a first electrode connected with the third electrode of the first transistor T1, a second electrode connected with the second electrode of the first transistor T1, and a third electrode (e.g., a gate electrode) connected with the j-th compensation scan line GCLj. The third transistor T3 may be turned on depending on the j-th compensation scan signal GCj transferred through the j-th compensation scan line GCLj and may diode-connect the first transistor T1 by connecting the third electrode of the first transistor T1 and the second electrode of the first transistor T1. One end of the third capacitor Nbst may be connected to the third electrode of the third transistor T3, and an opposite end of the third capacitor Nbst may be connected to the first node N1.

In an embodiment, the fourth transistor T4 is connected between the first initialization voltage line VL3 through which the first initialization voltage VINT is applied and the first node N1. The fourth transistor T4 includes a first electrode connected with the first initialization voltage line VL3 through which the first initialization voltage VINT is transferred, a second electrode connected with the first node N1, and a third electrode (e.g., a gate electrode) connected with the j-th initialization scan line GILj. The fourth transistor T4 is turned on depending on the j-th initialization scan signal GIj transferred through the j-th initialization scan line GILj. The turned-on fourth transistor T4 initializes the potential of the third electrode of the first transistor T1 (that is, the potential of the first node N1) by transferring the first initialization voltage VINT to the first node N1.

In an embodiment, the fifth transistor T5 includes a first electrode connected with the first drive voltage line VL1, a second electrode connected with the first electrode of the first transistor T1, and a third electrode (e.g., a gate electrode) connected to the j-th emission control line ECLj. The sixth transistor T6 includes a first electrode connected with the second electrode of the first transistor T1, a second electrode connected to the pixel electrode of the light emitting element ED (e.g., a second node N2), and a third electrode (e.g., a gate electrode) connected to the j-th emission control line ECLj.

In an embodiment, the fifth and sixth transistors T5 and T6, respectively, are simultaneously turned on depending on the j-th emission control signal EMj transferred through the j-th emission control line ECLj. The first drive voltage ELVDD applied through the turned-on fifth transistor T5 may be compensated for through the diode-connected first transistor T1 and thereafter may be transferred to the light emitting element ED through the sixth transistor T6.

In an embodiment, the seventh transistor T7 includes a first electrode connected to the second initialization voltage line VL4 through which the second initialization voltage VAINT is transferred, a second electrode electrically connected with the second electrode of the sixth transistor T6 (e.g., the second node N2), and a third electrode (e.g., a gate electrode) connected with the j-th black scan line GBLj. The second initialization voltage VAINT may have a voltage level lower than or equal to the voltage level of the first initialization voltage VINT.

In an embodiment, the one end of the first capacitor Cst is connected with the third electrode of the first transistor T1, and an opposite end of the first capacitor Cst is connected with the first drive voltage line VL1. A cathode of the light emitting element ED may be connected with the second drive voltage line VL2 that transfers the second drive voltage ELVSS. The second drive voltage ELVSS may have a lower voltage level than the first drive voltage ELVDD.

FIG. 6A is a plan view illustrating the first region A1 of the display panel, according to an embodiment. FIG. 6B is a plan view illustrating the second region A2 of the display panel, according to an embodiment.

In an embodiment and referring to FIGS. 4, 6A, and 6B, the display panel DP may include the first region A1 and the second region A2.

In an embodiment, the first region A1 may include an element region EP, the transmissive region TP, a copy element region CEP, and a bridge region BR. The transmissive region TP may be a region having a higher transmittance than the element region EP, the copy element region CEP, and the bridge region BR. In an embodiment, the transmissive region TP may be defined by a first opening BMop defined (provided or formed) in a first lower light blocking layer BML1.

In an embodiment, the plurality of pixels PX may be provided. The plurality of pixels PX may include first pixels PX11, PX12, and PX13 disposed in the first region A1 and second pixels PX21, PX22, and PX23 disposed in the second region A2. The arrangement rule of the first pixels PX11, PX12, and PX13 disposed in the first region A1 and the shapes of emissive regions defined in the first pixels PX11, PX12, and PX13 may be different from the arrangement rule of the second pixels PX21, PX22, and PX23 disposed in the second region A2 and the shapes of emissive regions defined in the second pixels PX21, PX22, and PX23.

In an embodiment, the first pixels PX11, PX12, and PX13 may include the first-first color pixel PX11 (or, referred to as a first red pixel), the first-second color pixel PX12 (or, referred to as a first green pixel), and the first-third color pixel PX13 (or, referred to as a first blue pixel). The second pixels PX21, PX22, and PX23 may include the second-first color pixel PX21 (or, referred to as a second red pixel), the second-second color pixel PX22 (or, referred to as a green pixel 2-1 or a green pixel 2-2), and the second-third color pixel PX23 (or, referred to as a second blue pixel).

In an embodiment and referring to FIG. 6A, at least a portion of the copy element region CEP may be surrounded by the transmissive region TP. In addition, the copy element region CEP may be spaced apart from the element region EP. The copy element region CEP may overlap the center TP-ec of a transmissive edge TP-e that defines the transmissive region TP. For example, only one copy element region CEP may overlap one transmissive region TP. In this case, the image quality of the first region A1 may be compensated for without a significant decrease in the transmittance of the transmissive region TP.

In an embodiment, the element region EP may include a main element region MEP and a plurality of connecting regions CP. The plurality of connecting regions CP may include a first connecting region CP1, a second connecting region CP2, a third connecting region CP3, and a fourth connecting region CP4 that extend from the main element region MEP in different directions. Each of the first to fourth connecting regions CP1, CP2, CP3, and CP4, respectively, may be disposed between two transmissive regions TP.

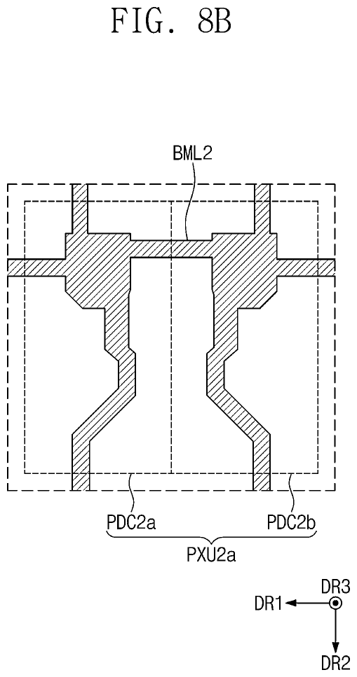

In an embodiment, each of the first pixels PX11, PX12, and PX13 may include a plurality of light emitting elements. For example, the first-first color pixel PX11 may include one pixel circuit PDC1a (refer to FIG. 8A), a plurality of first light emitting elements ED1, and a first connecting line CL1. For example, among the first light emitting elements ED1, one first light emitting element may be directly connected to the one pixel circuit PDC1a, and the remaining first light emitting elements may be referred to as first copy light emitting elements. The remaining first light emitting elements may operate in synchronization with the one first light emitting element.

In an embodiment, the first-second color pixel PX12 may include one pixel circuit PDC1b (refer to FIG. 8A), a plurality of second light emitting elements ED2 and ED2c, a copy light emitting element ED2cp, and a second connecting line CL2. The first-third color pixel PX13 may include one pixel circuit PDC1c (refer to FIG. 8A), a plurality of third light emitting elements ED3, and a third connecting line CL3.

In an embodiment, the first light emitting elements ED1 may be electrically connected with one another by the first connecting line CL1, the second light emitting elements ED2 and ED2c and the copy light emitting element ED2cp may be electrically connected with one another by the second connecting line CL2, the third light emitting elements ED3 may be connected with one another by the third connecting line CL3. That is, operations of the first light emitting elements ED1 may be controlled by the one pixel circuit PDC1a, operations of the second light emitting elements ED2 and ED2c and the copy light emitting element ED2cp may be controlled by the one pixel circuit PDC1b, and operations of the third light emitting elements ED3 may be controlled by the one pixel circuit PDC1c.

FIG. 6A illustrates an embodiment that four first light emitting elements ED1, one second light emitting element ED2, and four third light emitting elements ED3 are disposed in the main element region MEP, two second light emitting elements ED2c are disposed in the connecting regions CP, and the copy light emitting element ED2cp is disposed in the copy element region CEP. However, the arrangement relationship or the arrangement rule of the light emitting elements is not limited to the illustrated embodiment.

According to an embodiment, since the copy light emitting element ED2cp is disposed in the copy element region CEP, there may be obtained the same effect as additionally placing one pixel in the transmissive region TP. Accordingly, an effect in which the quality of an image displayed on the first region A1 is improved may occur. Thus, the display quality of the electronic device EDE (refer to FIG. 1A) may be improved.

According to an embodiment, the first light emitting elements ED1 may emit red light, the second light emitting elements ED2 and ED2c and the copy light emitting element ED2cp may emit green light, and the third light emitting elements ED3 may emit blue light. A human eye absorbs green light best, the green light having a wavelength of about 500 nanometers (nm). In other words, green light has the highest visibility. Accordingly, the second light emitting elements ED2 and ED2c and the copy light emitting element ED2cp emitting green light may be disposed in the connecting regions CP and the copy element region CEP. Thus, the quality of an image displayed on the first region A1 may be further improved.

In an embodiment and referring to FIG. 6B, a second pixel unit PXU2 may be disposed in the second region A2. The second pixel unit PXU2 may include a first sub-pixel unit PXU2a and a second sub-pixel unit PXU2b. The first sub-pixel unit PXU2a may include the second-third color pixel PX23 and the second-second color pixel PX22 (or, referred to as the second-second green pixel). The second sub-pixel unit PXU2b may include the second-first color pixel PX21 and the second-second color pixel PX22 (or, referred to as the second-first green pixel).

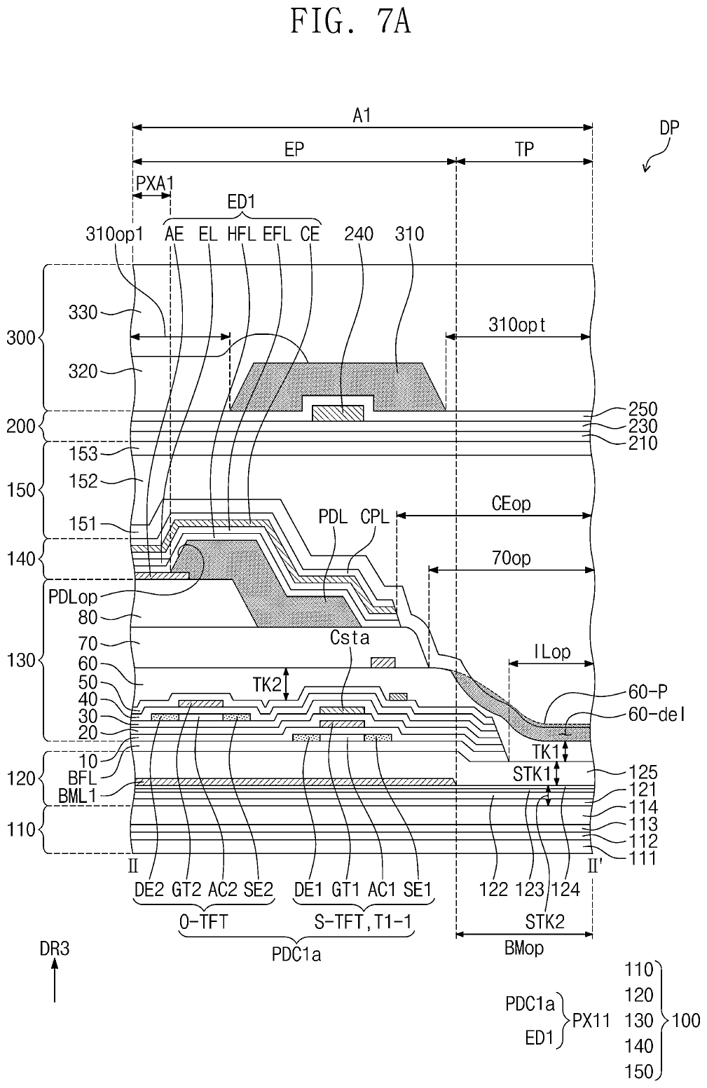

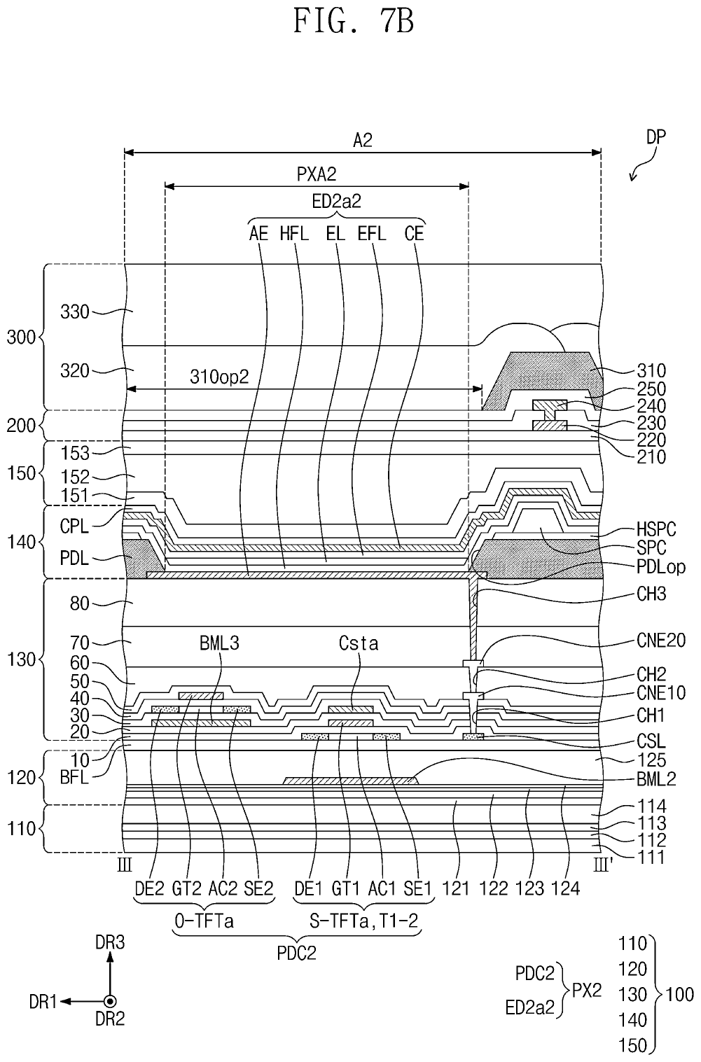

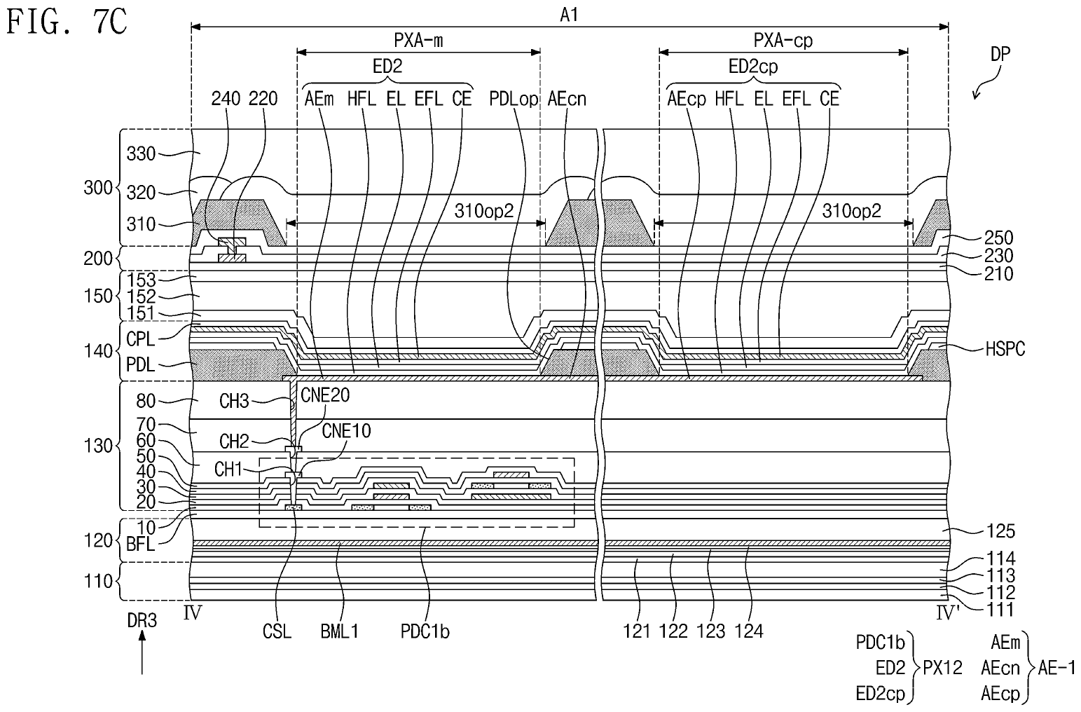

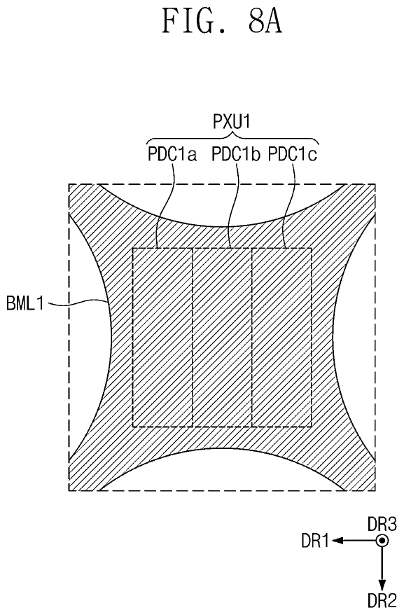

FIG. 7A is a sectional view illustrating the first region A1 of the display panel DP, according to an embodiment. FIG. 7B is a sectional view illustrating the second region A2 of the display panel DP, according to an embodiment. FIG. 7C is a sectional view illustrating the first region A1 of the display panel DP, according to an embodiment. FIG. 7A illustrates a section corresponding to line II-II′ of FIG. 6A, FIG. 7B illustrates a section corresponding to line III-III′ of FIG. 6B, and FIG. 7C illustrates a section corresponding to line IV-IV′ of FIG. 6A.

In an embodiment and referring to FIGS. 7A, 7B, and 7C, the display panel DP may include a display layer 100, a sensor layer 200, and an anti-reflection layer 300. The display layer 100 may include a base layer 110, a barrier layer 120, a circuit layer 130, an element layer 140, and an encapsulation layer 150.

In an embodiment, the base layer 110 may include first to fourth sub-base layers 111, 112, 113, and 114, respectively.

In an embodiment, each of the first sub-base layer 111 and the fourth sub-base layer 114 may include at least one of a polyimide-based resin, an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. Meanwhile, a “˜˜”-based resin as used herein may refer to a resin including a “˜˜” functional group. For example, each of the first and fourth sub-base layers 111 and 114, respectively, may include polyimide.

In an embodiment, each of the second sub-base layer 112 and the third sub-base layer 113 may include an inorganic material. For example, each of the second sub-base layer 112 and the third sub-base layer 113 may include at least one of silicon oxide, silicon nitride, silicon oxy nitride, and amorphous silicon. For example, the second sub-base layer 112 may include silicon oxy nitride, and the third sub-base layer 113 may include silicon oxide.

In an embodiment, the first sub-base layer 111 may be thicker than the fourth sub-base layer 114, but is not particularly limited thereto. The second sub-base layer 112 may be thinner than the third sub-base layer 113, but is not particularly limited thereto.

In an embodiment, the barrier layer 120 may be disposed on the base layer 110. The barrier layer 120 may include a plurality of sub-barrier layers 121, 122, 123, 124, and 125, the first lower light blocking layer BML1, and a second lower light blocking layer BML2.

In an embodiment, the first and second lower light blocking layers BML1 and BML2 may be referred to as first and second lower layers, first and second lower metal layers, first and second lower electrode layers, first and second lower shielding layers, first and second light blocking layers, first and second metal layers, first and second electrode layers, first and second shielding layers, or first and second overlap layers, respectively.

In an embodiment, the plurality of sub-barrier layers 121, 122, 123, 124, and 125 may include the first sub-barrier layer 121, the second sub-barrier layer 122, the third sub-barrier layer 123, the fourth sub-barrier layer 124, and the fifth sub-barrier layer 125 that are sequentially stacked in a direction away from the base layer 110. Each of the sub-barrier layers 121, 122, 123, 124, and 125 may include an inorganic material. For example, each of the sub-barrier layers 121, 122, 123, 124, and 125 may include at least one of silicon oxide, silicon nitride, silicon oxy nitride, and amorphous silicon. For example, the first sub-barrier layer 121 may include silicon oxy nitride, the second sub-barrier layer 122 may include silicon oxide, the third sub-barrier layer 123 may include amorphous silicon, the fourth sub-barrier layer 124 may include silicon oxide, and the fifth sub-barrier layer 125 may include silicon oxide.

In an embodiment, among the sub-barrier layers 121, 122, 123, 124, and 125, the fifth sub-barrier layer 125 is closest to the circuit layer 130. The fifth sub-barrier layer 125 may be referred to as a top sub-barrier layer. The thickness STK1 of the fifth sub-barrier layer 125 may be greater than the thicknesses of the first to fourth sub-barrier layers 121, 122, 123, and 124. For example, the thickness STK1 of the fifth sub-barrier layer 125 may be greater than the sum of the thicknesses STK2 of the sub-barrier layers 121, 122, 123, and 124.

In an embodiment, the first lower light blocking layer BML1 may be disposed in the first region A1, and the second lower light blocking layer BML2 may be disposed in the second region A2. The first lower light blocking layer BML1 and the second lower light blocking layer BML2 may be electrically insulated from each other, and different signals may be applied to the first lower light blocking layer BML1 and the second lower light blocking layer BML2. For example, a constant voltage having a certain voltage level may be applied to the first lower light blocking layer BML1, and the first drive voltage ELVDD (refer to FIG. 5) provided to the pixel circuit PDC (refer to FIG. 5) may be provided to the second lower light blocking layer BML2.

In an embodiment, the first lower light blocking layer BML1 and the second lower light blocking layer BML2 may be disposed on the same layer and may include the same material. For example, the first lower light blocking layer BML1 and the second lower light blocking layer BML2 may be disposed between the fourth sub-barrier layer 124 and the fifth sub-barrier layer 125. The first lower light blocking layer BML1 and the second lower light blocking layer BML2 may be covered by the fifth sub-barrier layer 125. Since the fifth sub-barrier layer 125 has the largest thickness among the sub-barrier layers 121, 122, 123, 124, and 125, the degree to which the characteristics of transistors are changed by the voltages provided to the first and second lower light blocking layers BML1 and BML2, respectively, may be decreased.

In an embodiment, the first lower light blocking layer BML1 may have the first opening BMop that defines the transmissive region TP. The first lower light blocking layer BML1 may be a pattern that functions as a mask when an electrode opening CEop is formed in a common electrode CE. For example, light applied from the rear surface of the base layer 110 toward the common electrode CE may pass through the first opening BMop of the first lower light blocking layer BML1 and may reach a portion of the common electrode CE and a portion of a capping layer CPL. That is, the portion of the common electrode CE and the portion of the capping layer CPL may be removed by the light passing through the first opening BMop of the first lower light blocking layer BML1. The light may be a laser beam.

In an embodiment, the first region A1, the region overlapping the first opening BMop of the first lower light blocking layer BML1 may be defined as the transmissive region TP, and the remaining region may be defined as the element region EP. The plurality of first pixels PX11, PX12, and PX13 (refer to FIG. 6A) may be disposed in the element region EP. The plurality of first pixels PX11, PX12, and PX13 may be spaced apart from the transmissive region TP.

In an embodiment, a buffer layer BFL may be disposed on the barrier layer 120. The buffer layer BFL may be provided in both the first region A1 and the second region A2. The buffer layer BFL may prevent diffusion of metal atoms or impurities from the base layer 110 to a first semiconductor pattern. Furthermore, the buffer layer BFL may allow the first semiconductor pattern to be uniformly formed, by adjusting the speed at which heat is provided during a crystallization process for forming the first semiconductor pattern.

In an embodiment, the buffer layer BFL may include a plurality of inorganic layers. For example, the buffer layer BFL may include a first sub-buffer layer including silicon nitride and a second sub-buffer layer that is disposed on the first sub-buffer layer and that includes silicon oxide. The buffer layer BFL may not overlap the transmissive region TP. That is, an opening corresponding to the transmissive region TP may be defined in the buffer layer BFL. Since the buffer layer BFL is not provided in the transmissive region TP, the transmittance of the transmissive region TP may be further improved.

In an embodiment, the first-first color pixel PX11 disposed in the first region A1, a second pixel PX2 disposed in the second region A2, and the first-second color pixel PX12 disposed in the first region A1 are illustrated in FIGS. 7A, 7B, and 7C, respectively. The second pixel PX2 may be one of the second pixels PX21, PX22, and PX23 (refer to FIG. 6B). The second pixel PX2 may include a second region light emitting element ED2a2 and a second pixel circuit PDC2.

In an embodiment and referring to FIG. 6A, the first-first color pixel PX11 may include the first light emitting elements ED1 and the first pixel circuit PDC1a. One first light emitting element ED1 is illustrated in FIG. 7A, and the remaining first light emitting elements ED1 may be electrically connected to the first pixel circuit PDC1a through the first connecting line CL1. The first-second color pixel PX12 may include the pixel circuit PDC1b, the plurality of second light emitting elements ED2 and ED2c, and the copy light emitting element ED2cp. In an embodiment and referring to FIG. 7C, the second light emitting element ED2 and the copy light emitting element ED2cp are illustrated. The second light emitting element ED2 may be electrically connected to the pixel circuit PDC1b. The copy light emitting element ED2cp may be electrically connected to the pixel circuit PDC1b via the second light emitting element ED2 through the second connecting line CL2.

In an embodiment, the circuit layer 130 may be disposed on the buffer layer BFL, and the element layer 140 may be disposed on the circuit layer 130.

In an embodiment and referring to FIG. 7A, a silicon thin film transistor S-TFT and an oxide thin film transistor O-TFT of the first pixel circuit PDC1a are illustrated as an example. The silicon thin film transistor S-TFT may be one of the transistors T1, T2, T5, T6, and T7 described with reference to FIG. 5, and the oxide thin film transistor O-TFT may be one of the third and fourth transistors T3 and T4, respectively. For example, the silicon thin film transistor S-TFT may be a first drive transistor T1-1 included in the first pixel circuit PDC1a.

In an embodiment, the transistors T1, T2, T3, T4, T5, T6, and T7 included in the first pixel circuit PDC1a may be referred to as first type transistors. In the first region A1, the first lower light blocking layer BML1 may overlap all of the first type transistors. That is, the first lower light blocking layer BML1 may completely overlap the region in which the first pixel circuit PDC1a is disposed. Accordingly, a voltage provided to the first lower light blocking layer BML1 may be provided irrespective of an operation of the first pixel circuit PDC1a.

In an embodiment and referring to FIG. 7B, a silicon thin film transistor S-TFTa and an oxide thin film transistor O-TFTa of the second pixel circuit PDC2 are illustrated as an example. The silicon thin film transistor S-TFTa may be the first transistor T1 described with reference to FIG. 5, and the oxide thin film transistor O-TFTa may be one of the third and fourth transistors T3 and T4, respectively. For example, the silicon thin film transistor S-TFTa may be a second drive transistor T1-2 included in the second pixel circuit PDC2.

In an embodiment, the transistors T1, T2, T3, T4, T5, T6, and T7 included in the second pixel circuit PDC2 may be referred to as second type transistors. In the second region A2, the second lower light blocking layer BML2 may overlap some of the second type transistors and may not overlap the other second type transistors. For example, the second lower light blocking layer BML2 may overlap a portion of the region in which the second pixel circuit PDC2 is disposed. In particular, the second lower light blocking layer BML2 may overlap the second drive transistor T1-2. Accordingly, a voltage provided to the second lower light blocking layer BML2 may be provided in synchronization with an operation of the second pixel circuit PDC2.

In an embodiment, FIGS. 7A, 7B, and 7C illustrate only a portion of the first semiconductor pattern disposed on the buffer layer BFL, and the first semiconductor pattern may be additionally disposed in another region. The first semiconductor pattern may be arranged across the pixels according to a specific rule. The first semiconductor pattern may have different electrical properties depending on whether the first semiconductor pattern is doped or not. The first semiconductor pattern may include a first region having a high conductivity and a second region having a low conductivity. The first region may be doped with an N-type dopant or a P-type dopant. A P-type transistor may include a doped region that is doped with a P-type dopant, and an N-type transistor may include a doped region that is doped with an N-type dopant. The second region may be an un-doped region, or may be a region more lightly doped than the first region.

In an embodiment, the conductivity of the first region may be higher than the conductivity of the second region, and the first region may substantially serve as an electrode or a signal line. The second region may substantially correspond to an active region (or, channel) of a transistor. In other words, one portion of the first semiconductor pattern may be the active region of the transistor, another portion may be a source or drain of the transistor, and another portion may be a connecting electrode or a connecting signal line.

In an embodiment, source regions SE1, active regions AC1, and drain regions DE1 of the silicon thin film transistors S-TFT and S-TFTa may be formed from the first semiconductor pattern. The source regions SE1 and the drain regions DE1 may extend from the active regions AC1 in opposite directions on the sections.

In an embodiment, portions of a connecting signal line CSL formed from the first semiconductor pattern is illustrated in FIGS. 7B and 7C. The connecting signal line CSL may be electrically connected to the sixth transistor T6 (refer to FIG. 5) and the seventh transistor T7 (refer to FIG. 5).

In an embodiment, the circuit layer 130 may include a plurality of inorganic layers and a plurality of organic layers. In an embodiment, insulating layers 10, 20, 30, 40, and 50 sequentially stacked on the buffer layer BFL may be inorganic layers, and insulating layers 60, 70, and 80 may be organic layers.

In an embodiment, the first insulating layer 10 may be disposed on the buffer layer BFL. The first insulating layer 10 may cover the first semiconductor pattern. The first insulating layer 10 may be an inorganic layer and/or an organic layer and may have a single-layer structure or a multi-layer structure. The first insulating layer 10 may include at least one of aluminum oxide, titanium oxide, silicon oxide, silicon nitride, silicon oxy nitride, zirconium oxide, and hafnium oxide. In an embodiment, the first insulating layer 10 may be a single silicon oxide layer. Not only the first insulating layer 10 but also the insulating layers of the circuit layer 130 that will be described below may have a single-layer structure or a multi-layer structure.

In an embodiment, a gate electrode GT1 of the silicon thin film transistor S-TFT or S-TFTa may be disposed on the first insulating layer 10. The gate electrode GT1 may be a portion of a metal pattern. The gate electrode GT1 may overlap the active region AC1. The gate electrode GT1 may function as a mask in a process of doping the first semiconductor pattern. The gate electrode GT1 may include titanium, silver, an alloy containing silver, molybdenum, an alloy containing molybdenum, aluminum, an alloy containing aluminum, aluminum nitride, tungsten, tungsten nitride, copper, indium tin oxide, or indium zinc oxide, but is not particularly limited thereto.

In an embodiment, the second insulating layer 20 may be disposed on the first insulating layer 10 and may cover the gate electrode GT1. The second insulating layer 20 may be an inorganic layer and may have a single-layer structure or a multi-layer structure. The second insulating layer 20 may include at least one of silicon oxide, silicon nitride, and silicon oxy nitride. In this embodiment, the second insulating layer 20 may have a single-layer structure including a silicon nitride layer.

In an embodiment, the third insulating layer 30 may be disposed on the second insulating layer 20. The third insulating layer 30 may be an inorganic layer and may have a single-layer structure or a multi-layer structure. For example, the third insulating layer 30 may have a multi-layer structure including a silicon oxide layer and a silicon nitride layer. One electrode Csta of the first capacitor Cst (refer to FIG. 5) may be disposed between the second insulating layer 20 and the third insulating layer 30. Furthermore, the other electrode of the first capacitor Cst may be disposed between the first insulating layer 10 and the second insulating layer 20.

In an embodiment, a second semiconductor pattern may be disposed on the third insulating layer 30. The second semiconductor pattern may include an oxide semiconductor. The oxide semiconductor may include a plurality of regions distinguished from each other depending on whether metal oxide is reduced or not. A region where metal oxide is reduced (hereinafter, referred to as the reduced region) has a higher conductivity than a region where metal oxide is not reduced (hereinafter, referred to as the non-reduced region). The reduced region substantially serves as a source/drain of a transistor or a signal line. The non-reduced region substantially corresponds to an active region (or, a semiconductor region or a channel) of the transistor. In other words, one portion of the second semiconductor pattern may be the active region of the transistor, another portion may be the source/drain region of the transistor, and another portion may be a signal transmission region.

In an embodiment, source regions SE2, active regions AC2, and drain regions DE2 of the oxide thin film transistors O-TFT and O-TFTa may be formed from the second semiconductor pattern. The source regions SE2 and the drain regions DE2 may extend from the active regions AC2 in opposite directions on the sections.

In an embodiment, the oxide thin film transistor O-TFT disposed in the first region A1 may overlap the first lower light blocking layer BML1. Accordingly, light incident from below the display panel DP may be blocked by the first lower light blocking layer BML1 and may not be provided to the active region AC2 of the oxide thin film transistor O-TFT.

In an embodiment, the oxide thin film transistor O-TFTa disposed in the second region A2 may not overlap the second lower light blocking layer BML2. Accordingly, a layer for blocking light incident to a lower portion of the oxide thin film transistor O-TFTa may be added. For example, a third lower light blocking layer BML3 may be disposed under the oxide thin film transistor O-TFTa disposed in the second region A2. The third lower light blocking layer BML3 may be disposed between the second insulating layer 20 and the third insulating layer 30. The third lower light blocking layer BML3 may include the same material as the one electrode Csta of the first capacitor Cst (refer to FIG. 5) and may be formed through the same process together with the one electrode Csta.

In an embodiment, the fourth insulating layer 40 may be disposed on the third insulating layer 30. The fourth insulating layer 40 may cover the second semiconductor pattern. The fourth insulating layer 40 may be an inorganic layer and may have a single-layer structure or a multi-layer structure. The fourth insulating layer 40 may include at least one of aluminum oxide, titanium oxide, silicon oxide, silicon nitride, silicon oxy nitride, zirconium oxide, and hafnium oxide. In an embodiment, the fourth insulating layer 40 may have a single-layer structure including silicon oxide.

In an embodiment, a gate electrode GT2 of the oxide thin film transistor O-TFT or O-TFTa may be disposed on the fourth insulating layer 40. The gate electrode GT2 may be a portion of a metal pattern. The gate electrode GT2 overlaps the active region AC2. The gate electrode GT2 may function as a mask in a process of reducing the second semiconductor pattern.

In an embodiment, the fifth insulating layer 50 may be disposed on the fourth insulating layer 40 and may cover the gate electrode GT2. The fifth insulating layer 50 may be an inorganic layer and/or an organic layer and may have a single-layer structure or a multi-layer structure. For example, in an embodiment, the fifth insulating layer 50 may have a multi-layer structure including a silicon oxide layer and a silicon nitride layer.

In an embodiment, a first connecting electrode CNE10 may be disposed on the fifth insulating layer 50. The first connecting electrode CNE10 may be connected to the connecting signal line CSL through a first contact hole CH1 penetrating the insulating layers 10, 20, 30, 40, and 50.

In an embodiment, a second opening ILop may be defined in the buffer layer BFL and at least some insulating layers among the plurality of insulating layers 10, 20, 30, 40, 50, 60, 70, and 80 included in the circuit layer 130. For example, the second opening ILop may be defined in the buffer layer BFL and the insulating layers 10, 20, 30, 40, and 50. The second opening ILop may be defined in a region overlapping the transmissive region TP. That is, the transmittance of the transmissive region TP may be improved by the removal of the portions of the buffer layer BFL and the insulating layers 10, 20, 30, 40, and 50 that overlap the transmissive region TP.

In an embodiment, the second opening ILop may have a smaller minimum width than the first opening BMop. Sidewalls of the buffer layer BFL and the insulating layers 10, 20, 30, 40, and 50 that define the second opening ILop may further protrude toward the transmissive region TP when compared to a sidewall of the first lower light blocking layer BML1.

In an embodiment, the sixth insulating layer 60 may be disposed on the fifth insulating layer 50. The sixth insulting layer 60 may include an organic material. The sixth insulating layer 60 may include a polyimide-based resin. For example, the sixth insulating layer 60 may include photosensitive polyimide. A second connecting electrode CNE20 may be disposed on the sixth insulating layer 60. The second connecting electrode CNE20 may be connected to the first connecting electrode CNE10 through a second contact hole CH2 penetrating the sixth insulating layer 60.

In an embodiment, the sixth insulating layer 60 may be disposed in both the element region EP and the transmissive region TP. The sixth insulating layer 60 may be referred to as a common organic layer. The sixth insulating layer 60 may fill the portion in which the second opening ILop is defined. That is, the sixth insulating layer 60 may overlap the transmissive region TP. Since the sixth insulating layer 60 is provided in the transmissive region TP, a step of the upper surface of the sixth insulating layer 60 may be decreased. When steps of layers overlapping the transmissive region TP are decreased, diffraction of light incident to the transmissive region TP may be alleviated (or, reduced). Accordingly, deformation of an image due to diffraction may be reduced, and thus the quality of an image obtained by the camera module CCM (refer to FIG. 2A) may be improved.

In an embodiment, a portion of a preliminary common organic layer 60-P disposed in the transmissive region TP may be removed in the thickness direction to form (or, provide) the sixth insulating layer 60. In FIG. 7A, the preliminary common organic layer 60-p is illustrated by a dotted line, and the removed portion 60-del is represented by dark hatching. A half-tone mask may be used to form the sixth insulating layer 60 from the preliminary common organic layer 60-p.

In an embodiment, the first thickness TK1 of the sixth insulating layer 60 in the transmissive region TP may be smaller than the second thickness TK2 of the sixth insulating layer 60 in the element region EP. For example, the first thickness TK1 may be a minimum thickness or an average thickness of the sixth insulating layer 60 in the transmissive region TP, and the second thickness TK2 may be a maximum thickness or an average thickness of the sixth insulating layer 60 in the element region EP. The first thickness TK1 may be greater than or equal to about 40% of the second thickness TK2 and less than about 100% of the second thickness TK2. As the difference between the first thickness TK1 and the second thickness TK2 is increased, the step of the upper surface of the sixth insulating layer 60 may be increased. In this case, in a process of making a conductive layer closest to the transmissive region TP subject to patterning, the conductive layer may be subjected to patterning (or, removed) by more than a designed value. That is, a probability that a line (or, wiring) becomes thin may be increased, and therefore a probability of defects may also be increased. When the first thickness TK1 is greater than or equal to about 40% of the second thickness TK2, the probability of defects may be decreased. Accordingly, the first thickness TK1 may be greater than or equal to about 40% the second thickness TK2. Thus, the transmittance of the transmissive region TP may be improved, and a side effect may be minimized.

In an embodiment, when the second thickness TK2 is about 15,000 angstroms, the first thickness TK1 may range from about 6,000 angstroms to about 10,000 angstroms. When the first thickness TK1 exceeds about 10,000 angstroms, an effect of transmittance improvement may be reduced. Accordingly, the first thickness TK1 may be determined within the range from about 40% of the second thickness TK2 to about 10,000 angstroms.

In an embodiment, the seventh insulating layer 70 may be disposed on the sixth insulating layer 60 and may cover the second connecting electrode CNE20. The eighth insulating layer 80 may be disposed on the seventh insulating layer 70.

In an embodiment, each of the sixth insulating layer 60, the seventh insulating layer 70, and the eighth insulating layer 80 may be an organic layer. In this specification, the sixth insulating layer 60 may be referred to as a first organic insulating layer, the seventh insulating layer 70 may be referred to as a second organic insulating layer, and the eighth insulating layer 80 may be referred to as a third organic insulating layer. For example, each of the sixth insulating layer 60, the seventh insulating layer 70, and the eighth insulating layer 80 may include a general purpose polymer, such as benzocyclobutene (BCB), polyimide, hexamethyldisiloxane (HMDSO), Polymethylmethacrylate (PMMA), or Polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or a blend thereof.

In an embodiment and referring to FIGS. 7A, 7B, and 7C, the element layer 140 including the first light emitting element ED1, the second region light emitting element ED2a2, the second light emitting element ED2, and the copy light emitting element ED2cp may be disposed on the circuit layer 130.

In an embodiment, each of the first light emitting element ED1 and the second region light emitting element ED2a2 may include a pixel electrode AE (or, an anode or a first electrode), a first functional layer HFL, an emissive layer EL, a second functional layer EFL, and the common electrode CE (or, the cathode or the second electrode). The second light emitting element ED2 and the copy light emitting element ED2cp may include a connecting pixel electrode AE-1, the first functional layer HFL, an emissive layer EL, the second functional layer EFL, and the common electrode CE (or, the cathode). The first functional layer HFL, the second functional layer EFL, and the common electrode CE may be commonly provided for the pixels PX (refer to FIG. 4).

In an embodiment, the pixel electrode AE and the connecting pixel electrode AE-1 may be disposed on the eighth insulating layer 80. The pixel electrode AE and the connecting pixel electrode AE-1 may be connected to the second connecting electrode CNE20 through a third contact hole CH3 that penetrates the seventh insulating layer 70 and the eighth insulating layer 80. The pixel electrode AE and the connecting pixel electrode AE-1 may be transmissive electrodes, semi-transmissive electrodes, or reflective electrodes. In an embodiment, the pixel electrode AE and the connecting pixel electrode AE-1 may include a reflective layer formed of silver, magnesium, aluminum, platinum, palladium, gold, nickel, neodymium, iridium, chromium, or a compound thereof and a transparent or translucent electrode layer formed on the reflective layer. The transparent or translucent electrode layer may include at least one selected from the group consisting of indium tin oxide, indium zinc oxide, indium gallium zinc oxide, zinc oxide, or indium oxide and aluminum-doped zinc oxide. For example, in an embodiment, the pixel electrode AE and the connecting pixel electrode AE-1 may include a multi-layer structure in which indium tin oxide, silver, and indium tin oxide are sequentially stacked.

In an embodiment, the connecting pixel electrode AE-1 may include a main pixel electrode AEm, a connecting electrode AEcn, and a copy pixel electrode AEcp. The main pixel electrode AEm may be included in the second light emitting element ED2, and the copy pixel electrode AEcp may be included in the copy light emitting element ED2cp. The connecting electrode AEcn may electrically connect the second light emitting element ED2 and the copy light emitting element ED2cp. The connecting electrode AEcn may be included in the bridge region BR illustrated in FIG. 6A. The connecting electrode AEcn may correspond to the second connecting line CL2 (refer to FIG. 6A) that is disposed in the bridge region BR.

In an embodiment, a pixel defining layer PDL may be disposed on the eighth insulating layer 80. The pixel defining layer PDL may have a property of absorbing light. For example, the pixel defining layer PDL may be black in color. The pixel defining layer PDL may include a black coloring agent. The black coloring agent may include a black dye or a black pigment. The black coloring agent may include carbon black, metal such as chromium, or oxide thereof.

In an embodiment, an opening PDLop for exposing a portion of the pixel electrode AE may be defined in the pixel defining layer PDL. That is, the pixel defining layer PDL may cover the periphery of the pixel electrode AE. In addition, the pixel defining layer PDL may cover a side surface of the eighth insulating layer 80 that is adjacent to the transmissive region TP. The pixel defining layer PDL may be spaced apart from a side surface of the seventh insulating layer 70 that is adjacent to the transmissive region TP. Accordingly, the pixel defining layer PDL may be stably brought into contact with the seventh insulating layer 70 and the eighth insulating layer 80.

In an embodiment, emissive regions may be defined by openings PDLop defined in the pixel defining layer PDL. The openings PDLop may be referred to as pixel defining openings. A first emissive region PXA1, a second emissive region PXA2, a third emissive region PXA-m, and a fourth emissive region PXA-cp may be defined in the first light emitting element ED1, the second region light emitting element ED2a2, the second light emitting element ED2, and the copy light emitting element ED2cp, respectively, by the openings PDLop. Since the third emissive region PXA-m and the fourth emissive region PXA-cp share the connecting pixel electrode AE-1, the third emissive region PXA-m and the fourth emissive region PXA-cp may simultaneously emit light.

In an embodiment, a spacer HSPC may be disposed on the pixel defining layer PDL. A protruding spacer SPC may be disposed on the spacer HSPC. The spacer HSPC and the protruding spacer SPC may be integrally formed with each other and may be formed of the same material. For example, the spacer HSPC and the protruding spacer SPC may be formed through the same process by a half-tone mask. However, this is illustrative, and the invention is not limited thereto. For example, the spacer HSPC and the protruding spacer SPC may include different materials and may be formed by separate processes.

In an embodiment, the first functional layer HFL may be disposed on the pixel electrode AE, the pixel defining layer PDL, the spacer HSPC, and the protruding spacer SPC. The first functional layer HFL may include a hole transport layer (HTL), may include a hole injection layer (HIL), or may include both the hole transport layer and the hole injection layer. The first functional layer HFL may be disposed throughout the first region A1 and the second region A2.

In an embodiment, the emissive layer EL may be disposed on the first functional layer HFL and may be disposed in a region corresponding to the opening PDLop of the pixel defining layer PDL. The emissive layer EL may include an organic material, an inorganic material, or an organic-inorganic material that emits certain color light. The emissive layer EL may be disposed in the first region A1 and the second region A2. The emissive layer EL disposed in the first region A1 may be disposed in the element region EP and the copy element region CEP other than the transmissive region TP.

In an embodiment, the second functional layer EFL may be disposed on the first functional layer HFL and may cover the emissive layer EL. The second functional layer EFL may include an electron transport layer (ETL), may include an electron injection layer (EIL), or may include both the electron transport layer and the electron injection layer. The second functional layer EFL may be disposed throughout the first region A1 and the second region A2.

In an embodiment, the common electrode CE may be disposed on the second functional layer EFL. The common electrode CE may be disposed in the first region A1 and the second region A2. The electrode opening CEop overlapping the first opening BMop may be defined in the common electrode CE. The electrode opening CEop may have a larger minimum width than the first opening BMop of the first lower light blocking layer BML1.

In an embodiment, the element layer 140 may further include the capping layer CPL disposed on the common electrode CE. The capping layer CPL may serve to improve light emission efficiency by the principle of constructive interference. The capping layer CPL may include, for example, a material having a refractive index of about 1.6 or more for light having a wavelength of about 589 nm. The capping layer CPL may be an organic capping layer including an organic material, an inorganic capping layer including an inorganic material, or a composite capping layer including an organic material and an inorganic material. For example, the capping layer CPL may include a carbocyclic compound, a heterocyclic compound, an amine group-containing compound, a porphine derivative, a phthalocyanine derivative, a naphthalocyanine derivative, an alkali metal complex, an alkaline earth metal complex, or a combination thereof. A substituent including O, N, S, Se, Si, F, Cl, Br, I, or a combination thereof may be selectively substituted for the carbocyclic compound, the heterocyclic compound, and the amine group-containing compound.

In an embodiment, t portion of the capping layer CPL that overlaps the electrode opening CEop of the common electrode CE may be removed. As a portion of the capping layer CPL that includes a portion overlapping the transmissive region TP and a portion of the common electrode CE are removed, the light transmittance of the transmissive region TP may be further improved.

In an embodiment, the encapsulation layer 150 may be disposed on the element layer 140. The encapsulation layer 150 may include an inorganic layer 151, an organic layer 152, and an inorganic layer 153 sequentially stacked one above another. However, layers constituting the encapsulation layer 150 are not limited thereto.

In an embodiment, the inorganic layers 151 and 153 may protect the element layer 140 from moisture and oxygen, and the organic layer 152 may protect the element layer 140 from foreign matter such as dust particles. The inorganic layers 151 and 153 may include a silicon nitride layer, a silicon oxy nitride layer, a silicon oxide layer, a titanium oxide layer, or an aluminum oxide layer. The organic layer 152 may include an acrylic organic layer, but is not limited thereto.

In an embodiment, the sensor layer 200 may be disposed on the display layer 100. The sensor layer 200 may be referred to as a sensor, an input sensing layer, or an input sensing panel. The sensor layer 200 may include a sensor base layer 210, a first sensor conductive layer 220, a sensor insulating layer 230, a second sensor conductive layer 240, and a sensor cover layer 250.

In an embodiment, the sensor base layer 210 may be directly disposed on the display layer 100. The sensor base layer 210 may be an inorganic layer including at least one of silicon nitride, silicon oxy nitride, and silicon oxide. In another embodiment, the sensor base layer 210 may be an organic layer including an epoxy resin, an acrylic resin, or an imide-based resin. The sensor base layer 210 may have a single-layer structure, or may have a multi-layer structure stacked in the third direction DR3.

In an embodiment, each of the first sensor conductive layer 220 and the second sensor conductive layer 240 may have a single-layer structure, or may have a multi-layer structure stacked in the third direction DR3.

In an embodiment, a conductive layer having a single-layer structure may include a metal layer or a transparent conductive layer. The metal layer may include molybdenum, silver, titanium, copper, aluminum, or an alloy thereof. The transparent conductive layer may include transparent conductive oxide such as indium tin oxide, indium zinc oxide, zinc oxide, or indium zinc tin oxide. In addition, the transparent conductive layer may include a conductive polymer such as PEDOT, a metal nano-wire, or graphene.

In an embodiment, a conductive layer having a multi-layer structure may include metal layers. The metal layers may have, for example, a three-layer structure of titanium/aluminum/titanium. The conductive layer having the multi-layer structure may include at least one metal layer and at least one transparent conductive layer.

In an embodiment, the sensor insulating layer 230 may be disposed between the first sensor conductive layer 220 and the second sensor conductive layer 240. The sensor insulating layer 230 may include an inorganic film. The inorganic film may include at least one of aluminum oxide, titanium oxide, silicon oxide, silicon nitride, silicon oxy nitride, zirconium oxide, and hafnium oxide.

In another embodiment, the sensor insulating layer 230 may include an organic film. The organic film may include at least one of an acrylic resin, a methacrylic resin, a polyisoprene resin, a vinyl resin, an epoxy resin, a urethane-based resin, a cellulosic resin, a siloxane-based resin, a polyimide resin, a polyamide resin, and a perylene-based resin.

In an embodiment, the sensor cover layer 250 may be disposed on the sensor insulating layer 230 and may cover the second sensor conductive layer 240. The second sensor conductive layer 240 may include a conductive pattern. The sensor cover layer 250 may cover the conductive pattern and may reduce or eliminate a probability of damage to the conductive pattern in a subsequent process.

In an embodiment, the sensor cover layer 250 may include an inorganic material. For example, the sensor cover layer 250 may include silicon nitride, but is not particularly limited thereto.

In an embodiment, the anti-reflection layer 300 may be disposed on the sensor layer 200. The anti-reflection layer 300 may include a dividing layer 310, a plurality of color filters 320, and a planarization layer 330. The dividing layer 310 and the color filters 320 are not disposed in the transmissive region TP of the first region A1.

In an embodiment, the dividing layer 310 may be disposed to overlap the conductive pattern of the second sensor conductive layer 240. The sensor cover layer 250 may be disposed between the dividing layer 310 and the second sensor conductive layer 240. The dividing layer 310 may prevent reflection of external light by the second sensor conductive layer 240. The material constituting the dividing layer 310 is not particularly limited as long as it is a material that absorbs light. The dividing layer 310 may be a black layer. In an embodiment, the dividing layer 310 may include a black coloring agent. The black coloring agent may include a black dye or a black pigment. The black coloring agent may include carbon black, metal such as chromium, or oxide thereof.

In an embodiment, a plurality of dividing openings 310op1 and 310op2 and a transmissive opening 310opt may be defined in the dividing layer 310. The plurality of dividing openings 310op1 and 310op2 may overlap the plurality of emissive layers EL, respectively. The color filters 320 may be disposed to correspond to the plurality of dividing openings 310op1 and 310op2. The color filters 320 may transmit light provided from the emissive layers EL overlapping the color filters 320.

In an embodiment, the transmissive opening 310opt of the dividing layer 310 may overlap the first opening BMop of the first lower light blocking layer BML1. The minimum width of the transmissive opening 310opt of the dividing layer 310 may be substantially the same as the minimum width of the first opening BMop of the first lower light blocking layer BML1. That is, in a region located adjacent to the transmissive region TP, an end of the dividing layer 310 may be substantially aligned with an end of the first lower light blocking layer BML1. Meanwhile, the expression “components are substantially aligned with each other or have substantially the same width” used herein means not only that the components are completely aligned with each other or the widths of the components are physically equal to each other, but also that despite the same design, the components are the same as each other within an error range occurring in a process.

In an embodiment, in a region located adjacent to the transmissive region TP, an end of the dividing layer 310 may protrude further toward the transmissive region TP when compared to an end of the pixel defining film PDL and an end of the common electrode CE.

In an embodiment, the planarization layer 330 may cover the dividing layer 310 and the color filters 320. The planarization layer 330 may include an organic material and may provide a flat surface on the upper surface of the planarization layer 330. In an embodiment, the planarization layer 330 may be omitted.

In an embodiment, the anti-reflection layer 300 may include a reflection control layer instead of the color filters 320. For example, in FIGS. 7A, 7B, and 7C, the color filters 320 may be omitted, and the reflection control layer may be added to the places where the color filters 320 are omitted. The reflection control layer may selectively absorb light in a partial band of light reflected inside the display panel and/or the electronic device or light in a partial band of light incident from outside the display panel and/or the electronic device.

In an embodiment, the reflection control layer may absorb light in a first wavelength range of about 490 nm to about 505 nm and light in a second wavelength range of about 585 nm to about 600 nm, and thus the light transmittance in the first wavelength range and the second wavelength range may be about 40% or less. The reflection control layer may absorb light outside the wavelength ranges of red light, green light, and blue light emitted from the emissive layers EL. Since the reflection control layer absorbs light outside the wavelength ranges of the red light, the green light, or the blue light emitted from the emissive layers EL as described above, a decrease in the luminance of the display panel and/or the electronic device may be prevented or minimized. In addition, deterioration in the light emission efficiency of the display panel and/or the electronic device may be prevented or minimized, and visibility may be improved.

In an embodiment, the reflection control layer may be implemented with an organic layer including a dye, a pigment, or a combination thereof. The reflection control layer may include a tetraazaporphyrin (TAP)-based compound, a porphyrin-based compound, a metal porphyrin-based compound, an oxazine-based compound, a squarylium-based compound, a triarylmethane-based compound, a polymethine-based compound, an anthraquinone-based compound, a phthalocyanine-based compound, an azo-based compound, a perylene-based compound, a xanthene-based compound, a diimmonium-based compound, a dipyrromethene-based compound, a cyanine-based compound, and a combination thereof.

In an embodiment, the reflection control layer may have a transmittance of about 64% to about 72%. The transmittance of the reflection control layer may be adjusted depending on the content of the pigment and/or dye included in the reflection control layer. The reflection control layer may overlap the emissive regions in the plan view, but may not overlap the transmissive region TP in the plan view.

FIG. 8A is a plan view illustrating a portion of the first lower light blocking layer BML1, according to an embodiment. FIG. 8B is a plan view illustrating a portion of the second lower light blocking layer BML2, according to an embodiment.

In an embodiment, a first pixel unit PXU1 overlapping the first lower light blocking layer BML1 is illustrated by a dotted line in FIG. 8A, and the first sub-pixel unit PXU2a overlapping the second lower light blocking layer BML2 is illustrated by a dotted line in FIG. 8B. An arrangement relationship between the second sub-pixel unit PXU2b (refer to FIG. 6B) and the second lower light blocking layer BML2 has substantially the same structure as an arrangement relationship between the first sub-pixel unit PXU2a and the second lower light blocking layer BML2, and therefore description thereabout will be omitted.

In an embodiment, the first pixel unit PXU1 may include three first pixel circuits PDC1a, PDC1b, and PDC1c. The second sub-pixel unit PXU2a may include two second pixel circuits PDC2a and PDC2b. Dotted regions illustrated in FIGS. 8A and 8B may correspond to regions in which the three first pixel circuits PDC1a, PDC1b, and PDC1c and the two second pixel circuits PDC2a and PDC2b are disposed.

In an embodiment and referring to FIGS. 8A and 8B, the first lower light blocking layer BML1 and the second lower light blocking layer BML2 may be disposed on the same layer and may be simultaneously formed through the same process. As a result, when compared to a process of forming first and second lower light blocking layers on different layers, a process of forming the first and second lower light blocking layers BML1 and BML2, respectively, according to this embodiment may omit a mask process once. Accordingly, a manufacturing process of the display panel DP (refer to FIG. 7A) may be simplified, and thus manufacturing costs of the display panel DP may be reduced.

In an embodiment, the first lower light blocking layer BML1 and the second lower light blocking layer BML2 may be disposed between the fourth sub-barrier layer 124 and the fifth sub-barrier layer 125 illustrated in FIGS. 7A, 7B, and 7C.

In an embodiment, the first lower light blocking layer BML1 and the second lower light blocking layer BML2 may be electrically insulated from each other. A constant voltage having a certain voltage level may be provided to the first lower light blocking layer BML1, and a power voltage provided to the second pixel circuit PDC2a or PDC2b may be provided to the second lower light blocking layer BML2. For example, the first drive voltage ELVDD (refer to FIG. 5) may be provided to the second lower light blocking layer BML2.

In an embodiment, the first lower light blocking layer BML1 may overlap the entire region in which the first pixel circuit PXU1 is disposed. Accordingly, the first lower blocking layer BML1 may overlap the first pixels PX11, PX12, and PX13 (refer to FIG. 6A) included in the first pixel unit PXU1. In the first region A1, the first lower light blocking layer BML1 may overlap all of the first type transistors that are included in the first pixels PX11, PX12, and PX13, respectively. Thus, the voltage provided to the first lower light blocking layer BML1 may be provided irrespective of operations of the first pixels PX11, PX12, and PX13.

In an embodiment, the second lower light blocking layer BML2 may overlap a portion of the region in which the first sub-pixel unit PXU2a is disposed. For example, the first sub-pixel unit PXU2a may include the second-second color pixel PX22 (refer to FIG. 6B) and the second-third color pixel PX23 (refer to FIG. 6B). In the second region A2, the second lower light blocking layer BML2 may overlap a part of the second type transistors that are included in the second-second color pixel PX22 and the second-third color pixel PX23, respectively. For example, the second lower light blocking layer BML2 may overlap the first transistor T1 (refer to FIG. 5). Accordingly, the voltage provided to the second lower light blocking layer BML2 may be provided in synchronization with operations of the second-second color pixel PX22 and the second-third color pixel PX23.

In an embodiment, each of the first lower light blocking layer BML1 and the second lower light blocking layer BML2 may have a single-layer structure or a multi-layer structure including a plurality of layers. For example, each of the first lower light blocking layer BML1 and the second lower light blocking layer BML2 may have a multi-layer structure in which titanium and molybdenum are sequentially stacked. A passage may be provided by cracks in the sub-barrier layers 121, 122, 123, and 124 (refer to FIG. 7A) and particles between the sub-barrier layers 121, 122, 123, and 124 (refer to FIG. 7A). In this case, hydrogen may be introduced through the passage, and the lower layers including titanium may serve to adsorb the hydrogen. Accordingly, a probability of a defect in a transistor caused by hydrogen may be reduced. In an embodiment, copper may be substituted for molybdenum. In another embodiment, each of the first lower light blocking layer BML1 and the second lower light blocking layer BML2 may include molybdenum or copper, but is not particularly limited thereto.

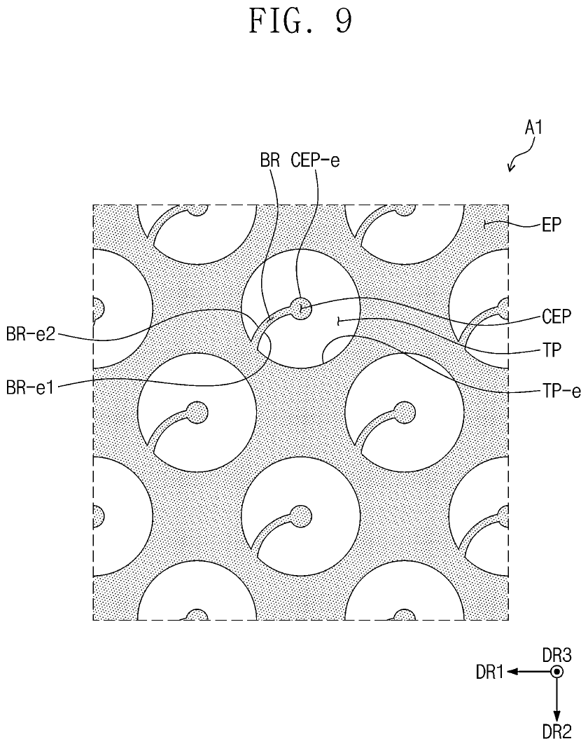

FIG. 9 is a plan view illustrating the first region A1 of the display panel, according to an embodiment.

In an embodiment and referring to FIGS. 6A and 9, the first region A1 may include the element region EP, the transmissive region TP, the copy element region CEP, and the bridge region BR. In FIG. 9, all of the remaining regions other than the transmissive region TP are represented by dark hatching. A plurality of transmissive regions TP may be defined (or, provided or formed). In addition, a plurality of copy element regions CEP and a plurality of bridge regions BR may be provided.

In an embodiment, the copy element regions CEP may be arranged to overlap the centers of the transmissive regions TP in a one-to-one correspondence. In addition, the bridge regions BR may be connected to the copy element regions CEP in a one-to-one correspondence. For example, one bridge region BR may extend from one copy element region CEP and may be connected with the element region EP. Wiring for electrically connecting the second light emitting element ED2 disposed in the element region EP and the copy light emitting element ED2cp disposed in the copy element region CEP may be disposed in the bridge region BR.

In an embodiment, the bridge region BR may include a first edge BR-e1 and a second edge BR-e2 that extend from the transmissive edge TP-e to the copy element region CEP. The bridge regions BR may have the same shape. For example, the bridge regions BR may extend with the same curvature from the same positions in the copy element regions CEP and may be connected to the element region EP.

In an embodiment, both the first edge BR-e1 and the second edge BR-e2 may have a curvature. In this case, even though the copy element region CEP and the bridge region BR, through which light does not transmit, are added to the transmissive region TP, a light burst phenomenon caused by the copy element region CEP and the bridge region BR may be minimized. Accordingly, the quality of an image displayed on the first region A1 may be improved, and the quality of a signal (e.g., an image) obtained by the camera module CMM disposed to overlap the first region A1 may not be deteriorated.

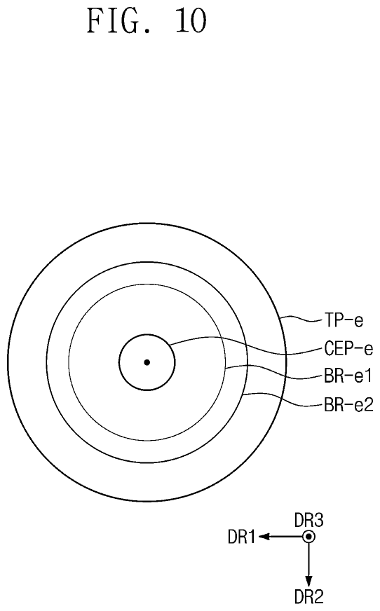

FIG. 10 is an image for explaining a relationship between radii of curvature, according to an embodiment. FIG. 10 illustrates circles having the radii of curvature of an edge CEP-e of the copy element region CEP, the first edge BR-e1, the second edge BR-e2, and the transmissive edge TP-e that are illustrated in FIG. 9.

In an embodiment and referring to FIGS. 9 and 10, the radius of curvature of the first edge BR-e1 and the radius of curvature of the second edge BR-e2 may be smaller than the radius of curvature of the transmissive edge TP-e. In an embodiment, the copy element region CEP may have a circular shape. In this case, the radius of curvature of the first edge BR-e1 and the radius of curvature of the second edge BR-e2 may be greater than the radius of curvature of the edge CEP-e of the copy element region CEP.

According to an embodiment, the radius of curvature of the first edge BR-e1 and the radius of curvature of the second edge BR-e2 may be different from each other. For example, the radius of curvature of the first edge BR-e1 may be smaller than the radius of curvature of the second edge BR-e2. However, this is illustrative, and the radius of curvature of the first edge BR-e1 may be greater than the radius of curvature of the second edge BR-e2. That is, to control the burst of light transmitting through the transmissive region TP, the radius of curvature of the first edge BR-e1 may be adjusted separately from the radius of curvature of the second edge BR-e2. Accordingly, the light burst phenomenon may be minimized.

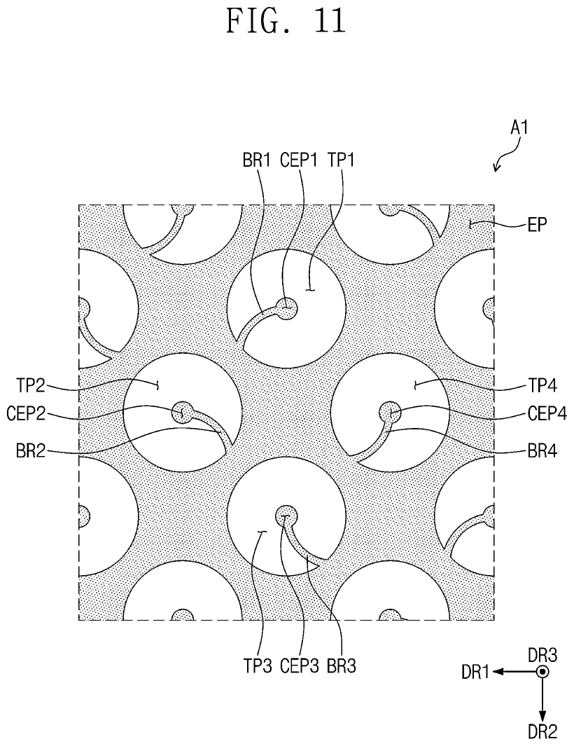

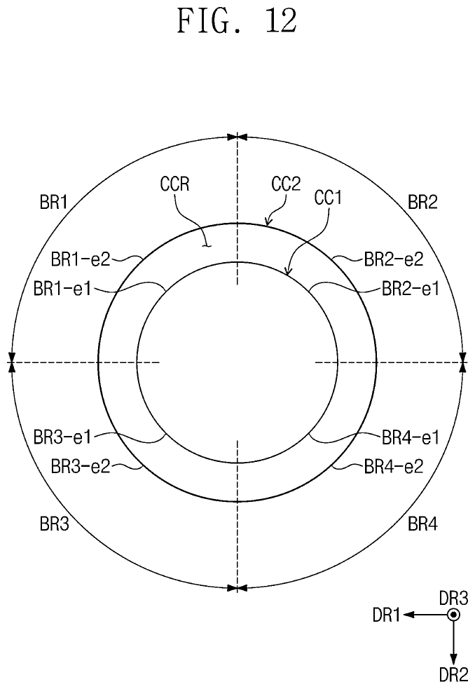

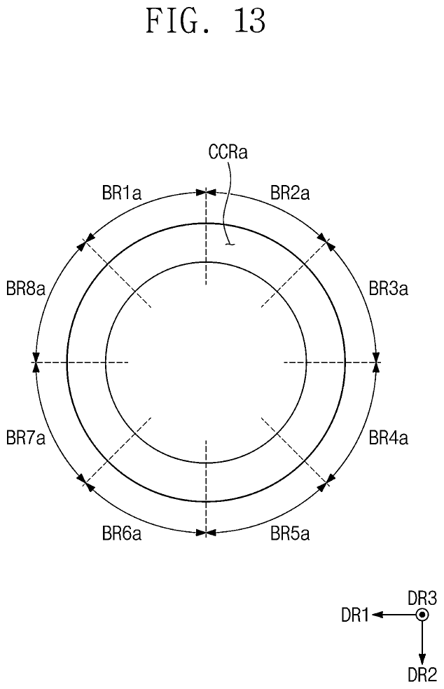

FIG. 11 is a plan view illustrating the first region A1 of the display panel, according to an embodiment. FIG. 12 is an image for explaining a relationship between bridge regions BR1, BR2, BR3, and BR4, according to an embodiment.

In an embodiment and referring to FIGS. 11 and 12, the first region A1 may include an element region EP, transmissive regions TP1, TP2, TP3, and TP4, copy element regions CEP1, CEP2, CEP3, and CEP4, and the bridge regions BR1, BR2, BR3, and BR4.

In an embodiment, the copy element regions CEP1, CEP2, CEP3, and CEP4 may be arranged to overlap the centers of the transmissive regions TP1, TP2, TP3, and TP4 in a one-to-one correspondence. In addition, the bridge regions BR1, BR2, BR3, and BR4 may be connected to the copy element regions CEP1, CEP2, CEP3, and CEP4 in a one-to-one correspondence. For example, one bridge region BR1 may extend from one copy element region CEP1 and may be connected with the element region EP.

In an embodiment, the shapes of the bridge regions BR1, BR2, BR3, and BR4 may have rotational symmetry. In FIG. 11, the four bridge regions BR1, BR2, BR3, and BR4 having different shapes and rotational symmetry are illustrated. That is, when the four bridge regions BR1, BR2, BR3, and BR4 are rotated, the four bridge regions BR1, BR2, BR3, and BR4 may have similar shapes that overlap each other.

In an embodiment, the bridge regions BR1, BR2, BR3, and BR4 may be disposed in the transmissive regions TP1, TP2, TP3, and TP4 and may serve as diffraction components. According to an embodiment, the extension directions or the arrangement forms of the bridge regions BR1, BR2, BR3, and BR4 may differ from one another. In this case, a phenomenon in which light transmitting through the transmissive regions TP1, TP2, TP3, and TP4 is burst in a specific direction may be minimized or reduced. Accordingly, the quality of a signal (e.g., an image) obtained by the camera module CMM disposed to overlap the first region A1 may not be deteriorated.

In an embodiment, the sum of the shapes of the adjacent bridge regions BR1, BR2, BR3, and BR4 may constitute at least a portion of a circular ring CCR. The circular ring CCR may be defined by a first circle CC1 and a second circle CC2. For example, first edges BR1-e1, BR2-e1, BR3-e1, and BR4-e1 of the bridge regions BR1, BR2, BR3, and BR4 may constitute the first circle CC1, and second edges BR1-e2, BR2-e2, BR3-e2, and BR4-e2 of the bridge regions BR1, BR2, BR3, and BR4 may constitute the second circle CC2.

In an embodiment, each of the lengths of the first edges BR1-e1, BR2-e1, BR3-e1, and BR4-e1 may correspond to about ¼ of the circumference of the first circle CC1, and each of the lengths of the second edges BR1-e2, BR2-e2, BR3-e2, and BR4-e2 may correspond to about ¼ of the circumference of the second circle CC2.

FIG. 13 is an image for explaining a relationship between bridge regions, according to an embodiment.

In an embodiment and referring to FIG. 13, the sum of the shapes of eight bridge regions BR1a, BR2a, BR3a, BR4a, BR5a, BR6a, BR7a, and BR8a may constitute at least a portion of a circular ring CCRa. In this case, the length of a first edge of each of the eight bridge regions BR1a, BR2a, BR3a, BR4a, BR5a, BR6a, BR7a, and BR8a may correspond to about ⅛ of the circumference of the inner circle of the circular ring CCRa. The length of a second edge longer than the first edge of each of the eight bridge regions BR1a, BR2a, BR3a, BR4a, BR5a, BR6a, BR7a, and BR8a may correspond to about ⅛ of the circumference of the outer circle of the circular ring CCRa.

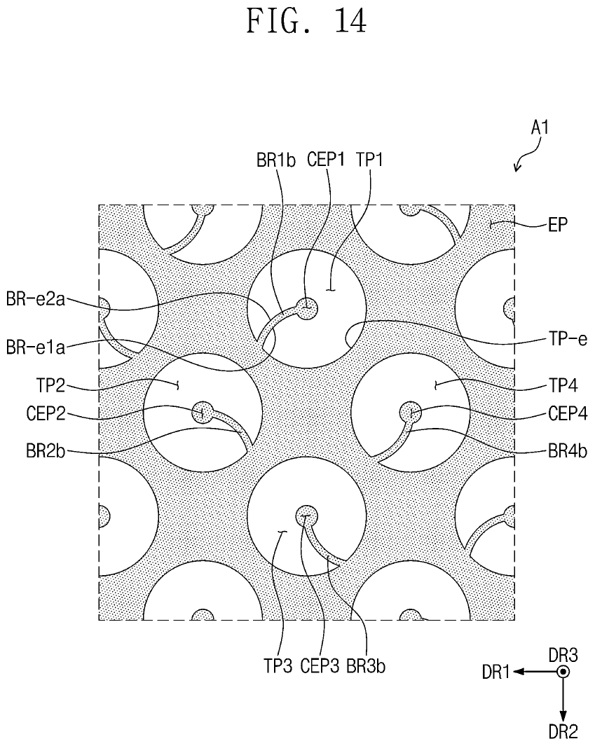

FIG. 14 is a plan view illustrating the first region A1 of the display panel, according to an embodiment.

In an embodiment and referring to FIG. 14, the first region A1 may include an element region EP, transmissive regions TP1, TP2, TP3, and TP4, copy element regions CEP1, CEP2, CEP3, and CEP4, and bridge regions BR1b, BR2b, BR3b, and BR4b.

In an embodiment, each of the bridge regions BR1b, BR2b, BR3b, and BR4b may include a first edge BR-e1a and a second edge BR-e2a that extend from a transmissive edge TP-e to the corresponding copy element region CEP. In an embodiment, both the first edge BR-e1a and the second edge BR-e2a may have a curvature, and the radii of curvature of the first edge BR-e1a and the second edge BR-e2a may be equal to each other.

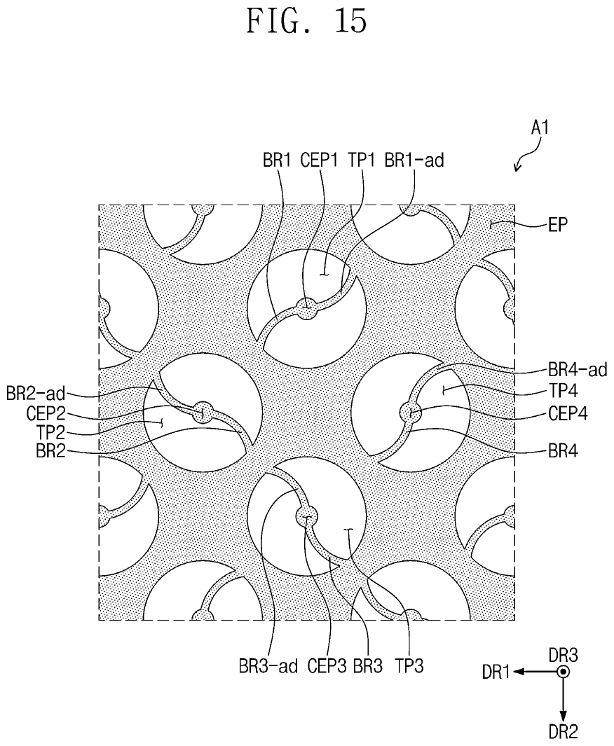

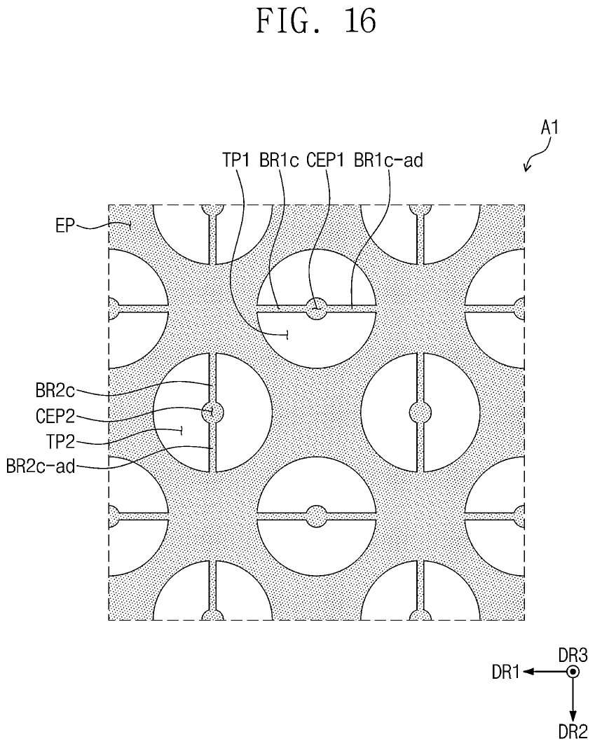

FIG. 15 is a plan view illustrating the first region A1 of the display panel, according to an embodiment.

In an embodiment and referring to FIG. 15, the first region A1 may include an element region EP, transmissive regions TP1, TP2, TP3, and TP4, copy element regions CEP1, CEP2, CEP3, and CEP4, bridge regions BR1, BR2, BR3, and BR4, and additional bridge regions BR1-ad, BR2-ad, BR3-ad, and BR4-ad.

In an embodiment, the bridge regions BR1, BR2, BR3, and BR4 may have rotational symmetry. In addition, the additional bridge regions BR1-ad, BR2-ad, BR3-ad, and BR4-ad may also have rotational symmetry. A first edge and a second edge of each of the bridge regions BR1, BR2, BR3, and BR4 and the additional bridge regions BR1-ad, BR2-ad, BR3-ad, and BR4-ad may have a curvature. The curvature of the first edge and the curvature of the second edge may be equal to or different from each other.

In an embodiment, one of the bridge regions BR1, BR2, BR3, and BR4 that overlaps one transmissive region TP1 among the transmissive regions TP1, TP2, TP3, and TP4 may be referred to as a first bridge region BR1, and one of the additional bridge regions BR1-ad, BR2-ad, BR3-ad, and BR4-ad that overlaps the one transmissive region TP1 may be referred to as a second bridge region BR1-ad. The first bridge region BR1 and the second bridge region BR1-ad may extend from one copy element region CEP1. In particular, the first bridge region BR1 and the second bridge region BR1-ad may extend from the one copy element region CEP1 in opposite directions.

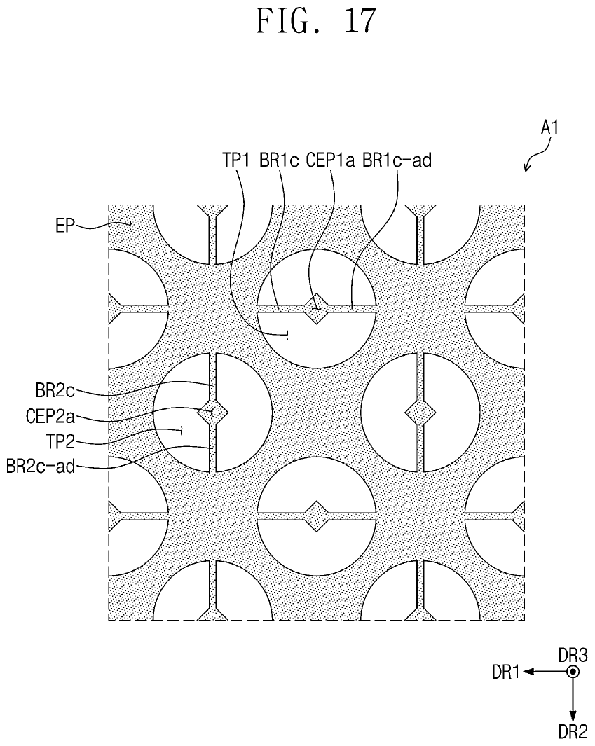

FIG. 16 is a plan view illustrating the first region A1 of the display panel, according to an embodiment.

In an embodiment and referring to FIG. 16, the first region A1 may include an element region EP, transmissive regions TP1 and TP2, copy element regions CEP1 and CEP2, bridge regions BR1c and BR2c, and additional bridge regions BR1c-ad and BR2c-ad.

In an embodiment, the bridge regions BR1c and BR2c may have rotational symmetry. In addition, the additional bridge regions BR1c-ad and BR2c-ad may also have rotational symmetry. For example, when one bridge region BR1c is rotated by about 90 degrees, the one bridge region BR1c may correspond to the shape of another bridge region BR2c.

In an embodiment, edges of the bridge regions BR1c and BR2c and the additional bridge regions BR1c-ad and BR2c-ad may not have a curvature. For example, the edges may all have a straight-line shape.

In an embodiment, one or more bridge regions may be connected to one copy element region CEP1. For example, one bridge region BR1c and one additional bridge region BR1c-ad may be connected to the copy element region CEP1. The one bridge region BR1c and the one additional bridge region BR1c-ad may extend from the copy element region CEP1 in opposite directions.

FIG. 17 is a plan view illustrating the first region A1 of the display panel, according to an embodiment.

In an embodiment and referring to FIG. 17, the first region A1 may include an element region EP, transmissive regions TP1 and TP2, copy element regions CEP1a and CEP2a, bridge regions BR1c and BR2c, and additional bridge regions BR1c-ad and BR2c-ad. In an embodiment, each of the copy element regions CEP1a and CEP2a may have a polygonal shape.

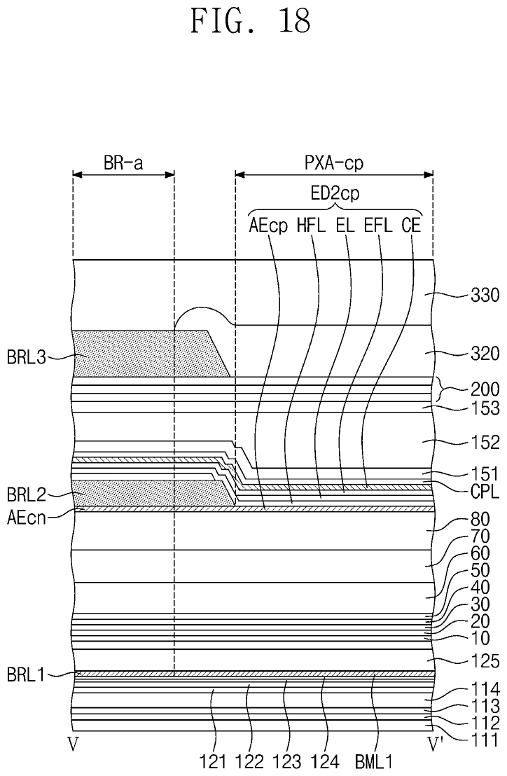

FIG. 18 is a sectional view of the display panel, according to an embodiment.

In an embodiment and referring to FIGS. 7A, 7C, 9, and 18, a first bridge layer BRL1, a second bridge layer BRL2, and a third bridge layer BRL3 may be disposed in a bridge region BR-a. Each of the bridge layers BRL1, BRL2, and BRL3 may have a light blocking function.

In an embodiment, the first bridge layer BRL1 may be a pattern that functions as a mask when the electrode opening CEop is formed in the common electrode CE. The first bridge layer BRL1 may include the same material as the first lower light blocking layer BML1 and may be disposed on the same layer as the first lower light blocking layer BML1. That is, the first bridge layer BRL1 may be formed by the same process as the first lower light blocking layer BML1 and may have an integral shape connected with the first lower light blocking layer BML1. For example, when the electrode opening CEop is formed in the common electrode CE, a process of removing a portion of the common electrode may be performed. This process may be performed through a laser lift off (LLO) process. In the above-described process, the first bridge layer BRL1 and the first lower light blocking layer BML1 may serve as a mask that blocks a laser. Accordingly, the common electrode CE may not be removed in the portion that overlaps the first bridge layer BRL1 and the first lower light blocking layer BML1.

In an embodiment, the second bridge layer BRL2 may include the same material as the pixel defining layer PDL and may be disposed on the same layer as the pixel defining layer PDL. The second bridge layer BRL2 may be formed by the same process as the pixel defining layer PDL. The third bridge layer BRL3 may include the same material as the dividing layer 310 (refer to FIG. 7A) and may be disposed on the same layer as the dividing layer 310. The third bridge layer BRL3 may be formed by the same process as the dividing layer 310.

In an embodiment, the shape of the bridge region BR-a and a light burst level of light transmitting through the transmissive region TP may be controlled using the shape of one of the bridge layers BRL1, BRL2, and BRL3. For example, when viewed from above the plane, each of the bridge layers BRL1, BRL2, and BRL3 may correspond to the shapes of the bridge regions described with reference to FIGS. 9, 11, 14, 15, 16, and 17.

In an embodiment, the connecting electrode AEcn that electrically connects the second light emitting element ED2 and the copy light emitting element ED2cp may be disposed in the bridge region BR-a. Although FIG. 18 illustrates an example that the connecting electrode AEcn includes the same material as the copy pixel electrode AEcp and is disposed on the same layer as the copy pixel electrode AEcp, the invention is not particularly limited thereto. For example, in an embodiment, the connecting electrode AEcn may be implemented with a conductive layer disposed between the seventh insulating layer 70 and the eighth insulating layer 80, but is not particularly limited thereto. In this case, the second bridge layer BRL2 may be omitted.

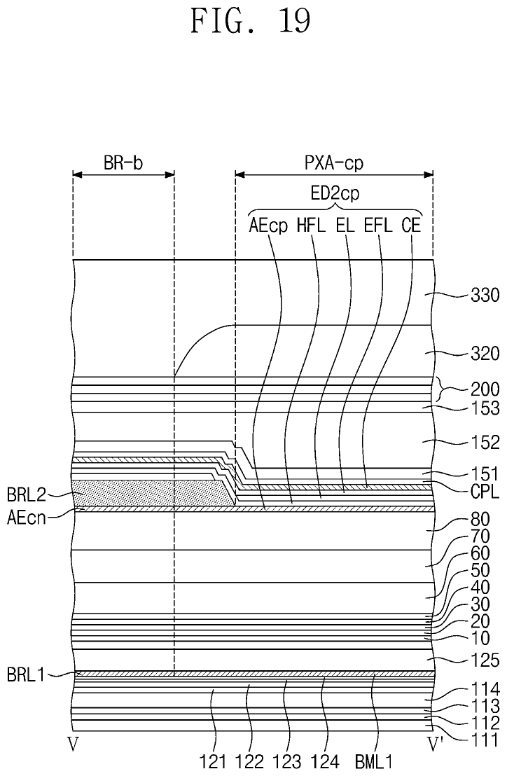

FIG. 19 is a sectional view of the display panel, according to an embodiment.

In an embodiment and referring to FIGS. 7A, 9, and 19, a first bridge layer BRL1 and a second bridge layer BRL2 may be disposed in a bridge region BR-b. Each of the first bridge layer BRL1 and the second bridge layer BRL2 may have a light blocking function.

In an embodiment, the first bridge layer BRL1 may include the same material as the first lower light blocking layer BML1 and may be disposed on the same layer as the first lower light blocking layer BML1. That is, the first bridge layer BRL1 may be formed by the same process as the first lower light blocking layer BML1 and may have an integral shape connected with the first lower light blocking layer BML1. The second bridge layer BRL2 may include the same material as the pixel defining layer PDL and may be disposed on the same layer as the pixel defining layer PDL. The second bridge layer BRL2 may be formed by the same process as the pixel defining layer PDL.

In an embodiment, the shape of the bridge region BR-b and a light burst level of light transmitting through the transmissive region TP may be controlled using the shape of one of the first and second bridge layers BRL1 and BRL2, respectively. For example, when viewed from above the plane, each of the first and second bridge layers BRL1 and BRL2, respectively, may correspond to the shapes of the bridge regions described with reference to FIGS. 9, 11, 14, 15, 16, and 17.

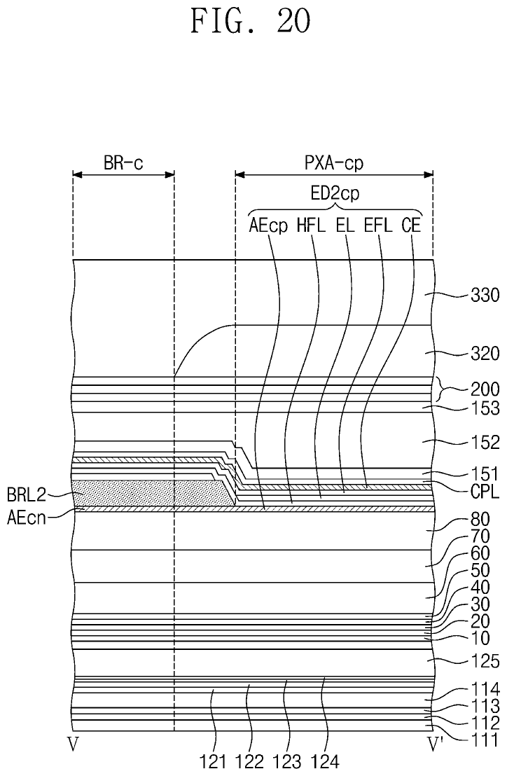

FIG. 20 is a sectional view of the display panel, according to an embodiment.

In an embodiment and referring to FIG. 20, a second bridge layer BRL2 may be disposed in a bridge region BR-c. The second bridge layer BRL2 may have a light blocking function. The second bridge layer BRL2 may include the same material as the pixel defining layer PDL and may be disposed on the same layer as the pixel defining layer PDL. The second bridge layer BRL2 may be formed by the same process as the pixel defining layer PDL.

In an embodiment, the shape of the bridge region BR-c and a light burst level of light transmitting through the transmissive region TP may be controlled using the shape of the second bridge layer BRL2. For example, when viewed from above the plane, the second bridge layer BRL2 may correspond to the shapes of the bridge regions described with reference to FIGS. 9, 11, 14, 15, 16, and 17.

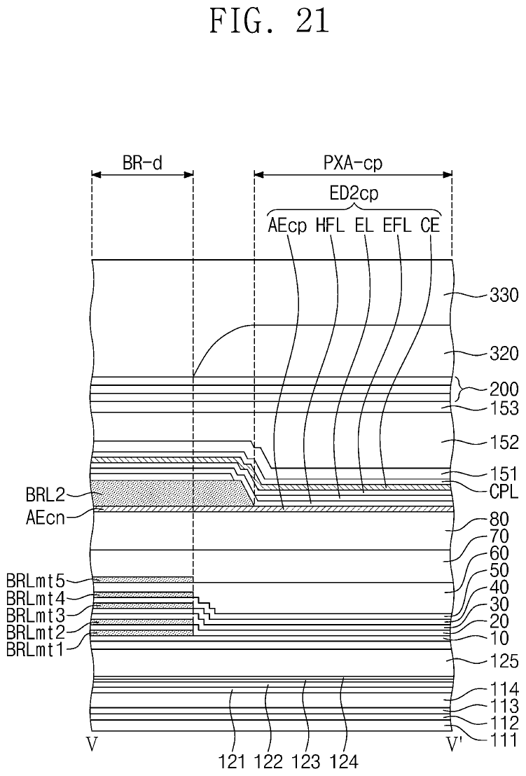

FIG. 21 is a sectional view of the display panel, according to an embodiment.

In an embodiment and referring to FIGS. 7B and 21, a second bridge layer BRL2 and a plurality of bridge metal layers BRLmt1, BRLmt2, BRLmt3, BRLmt4, and BRLmt5 may be disposed in a bridge region BR-d. Components disposed in the bridge region BR-d are not limited to the aforementioned components. At least a part of the aforementioned components may be omitted, and other components may be added.

In an embodiment, the plurality of bridge metal layers BRLmt1, BRLmt2, BRLmt3, BRLmt4, and BRLmt5 may include the same material as at least one of a plurality of conductive layers included in the circuit layer 130. For example, the first bridge metal layer BRLmt1 may include the same material as the gate electrode GT1, the second bridge metal layer BRLmt2 may include the same material as the one electrode Csta of the first capacitor Cst (refer to FIG. 5), the third bridge metal layer BRLmt3 may include the same material as the gate electrode GT2, the fourth bridge metal layer BRLmt4 may include the same material as the first connecting electrode CNE10, and the fifth bridge metal layer BRLmt5 may include the same material as the second connecting electrode CNE20.

In an embodiment and as described above, the first region of the display panel may include the element region, the transmissive region, the copy element region, and the bridge region connected to the element region and the copy element region. One transmissive region may surround at least a portion of one copy element region, and a copy light emitting element may be disposed in the copy element region. In this embodiment, the quality of an image displayed on the first region may be compensated for without a significant decrease in the transmittance of the transmissive region. Thus, the display quality of the electronic device may be improved.

In an embodiment, the edges of the bridge region may all have a curvature. In this case, even though the bridge region, through which light does not transmit, is added to the transmissive region, a light burst phenomenon caused by the bridge region may be minimized. Accordingly, the quality of an image displayed on the first region may be improved, and the quality of a signal (e.g., an image) obtained by the electronic module disposed to overlap the first region may not be deteriorated. Accordingly, the product performance of the electronic device may be improved.

While the invention has been described with reference to embodiments thereof, it will be apparent to those of ordinary skill in the art that various changes and modifications may be made thereto without departing from the spirit and scope of the invention. Therefore, the scope of the invention is not limited to the contents described in the detailed description of the specification. Moreover, the embodiments or parts of the embodiments may be combined in whole or in part without departing from the scope of the invention.

What is claimed is:

1. An electronic device comprising:
a display panel including a first region and a second region spaced apart from the first region, wherein the first region includes an element region, a transmissive region disposed adjacent to the element region, a copy element region spaced apart from the element region and partially surrounded by the transmissive region, and a bridge region connected to the copy element region and the element region,
wherein the display panel includes:
a plurality of light emitting elements disposed in the element region; and
a copy light emitting element which operates in synchronization with one of the plurality of light emitting elements and disposed in the copy element region, and
wherein the copy element region overlaps a center of a transmissive edge to define the transmissive region.

2. The electronic device of claim 1, wherein the bridge region includes a first edge extending from the transmissive edge to the copy element region and a second edge extending from the transmissive edge to the copy element region, wherein both the first edge and the second edge have a curvature.

3. The electronic device of claim 2, wherein a radius of curvature of the first edge is different from a radius of curvature of the second edge.

4. The electronic device of claim 2, wherein a radius of curvature of the first edge and a radius of curvature of the second edge are smaller than a radius of curvature of the transmissive edge.

5. The electronic device of claim 2, wherein the copy element region has a circular shape, and
wherein a radius of curvature of the first edge and a radius of curvature of the second edge are greater than a radius of curvature of the copy element region.

6. The electronic device of claim 1, wherein the transmissive region includes a plurality of transmissive regions, the copy element region includes a plurality of copy element regions, and the bridge region includes a plurality of bridge regions, and
wherein the plurality of copy element regions overlap a center of each of the plurality of transmissive regions in a one-to-one correspondence.

7. The electronic device of claim 6, wherein the plurality of bridge regions are connected to the plurality of copy element regions in a one-to-one correspondence.

8. The electronic device of claim 7, wherein a shape of each of the plurality of bridge regions are the same shape.

9. The electronic device of claim 7, wherein a shape of each of the plurality of bridge regions have rotational symmetry.

10. The electronic device of claim 7, wherein a sum of a shape of each of the plurality of bridge regions which are disposed adjacent to each other constitutes at least a portion of a circular ring.

11. The electronic device of claim 6, wherein one or more bridge regions among the plurality of bridge regions are connected to one copy element region among the plurality of copy element regions.

12. The electronic device of claim 11, wherein the one or more bridge regions include a first bridge region and a second bridge region, wherein the first bridge region and the second bridge region extend from the one copy element region in opposite directions.

13. The electronic device of claim 1, wherein the copy element region has a polygonal shape.

14. The electronic device of claim 1, wherein the display panel further includes:
a base layer;
a circuit layer disposed on the base layer, wherein the circuit layer includes a plurality of conductive layers;
an element layer disposed on the circuit layer, wherein the element layer includes the plurality of light emitting elements and the copy light emitting element; and
an encapsulation layer disposed on the element layer,
wherein each of the plurality of light emitting elements and the copy light emitting element includes a pixel electrode, an emissive layer disposed on the pixel electrode, and a common electrode disposed on the emissive layer, and
wherein the common electrode includes an electrode opening defined therein to overlap the transmissive region.

15. The electronic device of claim 14, wherein the display panel further includes a lower light blocking layer disposed between the base layer and the circuit layer, and
wherein the lower light blocking layer overlaps the element region, the copy element region, and the bridge region and includes an opening defined therein to overlap the transmissive region.

16. The electronic device of claim 14, wherein at least one bridge layer is disposed in the bridge region and includes a same material as at least one of the plurality of conductive layers.

17. The electronic device of claim 14, wherein the element layer further includes a pixel defining layer disposed on the circuit layer and including a pixel defining opening defined therein to expose at least a portion of the pixel electrode, and
wherein a bridge layer including a same material as the pixel defining layer is disposed in the bridge region.

18. The electronic device of claim 14, wherein the display panel further includes a dividing layer disposed on the encapsulation layer and including a dividing opening and a transmissive opening defined therein, wherein the dividing opening overlaps the pixel electrode, and the transmissive opening overlaps the transmissive region, and
wherein a bridge layer including a same material as the dividing layer is disposed in the bridge region.

19. The electronic device of claim 1, wherein the plurality of light emitting elements include a first light emitting element which emits red light, a second light emitting element which emits green light, and a third light emitting element which emits blue light, and
wherein the copy light emitting element operates in synchronization with the second light emitting element and emits the green light.

20. An electronic device comprising:
a display panel including a first region and a second region spaced apart from the first region, wherein the first region includes an element region, a transmissive region disposed adjacent to the element region, a copy element region spaced apart from the element region and partially surrounded by the transmissive region, and a bridge region connected to the copy element region and the element region,
wherein the display panel includes:
a plurality of light emitting elements disposed in the element region; and
a copy light emitting element which operates in synchronization with one of the plurality of light emitting elements and which is disposed in the copy element region, and
wherein the bridge region includes a first edge extending to the copy element region from a transmissive edge to define the transmissive region and a second edge extending to the copy element region from the transmissive edge, wherein a radius of curvature of the first edge is different from a radius of curvature of the second edge.

21. The electronic device of claim 20, wherein the radius of curvature of the first edge and the radius of curvature of the second edge are smaller than a radius of curvature of the transmissive edge.

22. The electronic device of claim 20, wherein the copy element region has a circular shape, and
wherein the radius of curvature of the first edge and the radius of curvature of the second edge are greater than a radius of curvature of the copy element region.

23. The electronic device of claim 20, wherein the transmissive region includes a plurality of transmissive regions, the copy element region includes a plurality of copy element regions, and the bridge region includes a plurality of bridge regions,
wherein the plurality of copy element regions overlap a center of each of the plurality of transmissive regions in a one-to-one correspondence,
wherein the plurality of bridge regions are connected to the plurality of copy element regions in a one-to-one correspondence, and
wherein a shape of each of the plurality of bridge regions have rotational symmetry.

24. The electronic device of claim 23, wherein the sum of each of the shapes of the plurality of bridge regions disposed adjacent to each other among the plurality of bridge regions constitutes at least a portion of a circular ring.

25. An electronic device comprising:
a display panel including a first region and a second region spaced apart from the first region, wherein the first region includes an element region, a transmissive region disposed adjacent to the element region, a copy element region spaced apart from the element region and partially surrounded by the transmissive region, and a bridge region connected to the copy element region and the element region,
wherein the display panel includes:
a first light emitting element disposed in the element region and which emits red light;
a second light emitting element disposed in the element region and which emits green light;
a third light emitting element disposed in the element region and which emits blue light; and
a copy light emitting element disposed in the copy element region and which operates in synchronization with the second light emitting element and which emits the green light, and
wherein only the copy light emitting element is disposed in the copy element region.
